(19) United States
(12) Patent Application Publication
(10) Pub. No.: US 2023/0197673 A1
(43) Pub. Date: Jun. 22, 2023

(54) SEMICONDUCTOR DEVICE MANUFACTURING METHOD AND SEMICONDUCTOR DEVICE

(71) Applicant: FUJI ELECTRIC CO., LTD., Kawasaki-shi (JP)

(72) Inventor: Hisato INOKUCHI, Matsumoto-city (JP)

(73) Assignee: FUJI ELECTRIC CO., LTD., Kawasaki-shi (JP)

(21) Appl. No.: 17/975,394

(22) Filed: Oct. 27, 2022

(30) Foreign Application Priority Data
Dec. 16, 2021 (JP) 2021-203959

(51) Int. Cl. H01L 23/00; H01L 23/544

(52) U.S. Cl. CPC H01L 24/83; H01L 23/544; H01L 2223/54426; H01L 2224/32225; H01L 24/32; H01L 2224/29111; H01L 2224/29139; H01L 2224/29147; H01L 2224/29118; H01L 2224/29113; H01L 2224/29109; H01L 24/29; H01L 2224/48227; H01L 24/48; H01L 2224/45144; H01L 2224/45139; H01L 2224/45147; H01L 2224/45124; H01L 24/45; H01L 2224/73265; H01L 24/73; H01L 2224/8314

(57) ABSTRACT

A regulating jig that includes one end, the other end, and a groove having opposite regulating surfaces formed therein, between the one end and the other end is set on a positioning jig. At this time, the regulating surfaces are positioned at sides of the regulating member entering the groove, and the one end and the other end of the regulating jig are positioned on respective opposite sides of the opening edge of an opening area of the positioning jig. Then, a base substrate, a solder sheet, and an insulated circuit substrate are heated to bond the insulated circuit substrate to the base substrate.

### CROSS-REFERENCE TO RELATED APPLICATION

This application is based upon and claims the benefit of priority of the prior Japanese Patent Application No. 2021-203959, filed on Dec. 16, 2021, the entire contents of which are incorporated herein by reference.

### BACKGROUND OF THE INVENTION

### 1. Field of the Invention

The embodiments discussed herein relate to a semiconductor device manufacturing method and a semiconductor device.

### 2. Background of the Related Art

In a semiconductor device, a base substrate and an insulated circuit substrate including semiconductor chips are laminated in order from the bottom. The insulated circuit substrate is bonded to the base substrate using solder. The semiconductor chips include insulated gate bipolar transistors (IGBTs) and power metal oxide semiconductor field effect transistors (MOSFETs), for example. The insulated circuit substrate includes an insulating plate, a metal plate disposed on the rear surface of the insulating plate, and a plurality of circuit patterns formed on the front surface of the insulating plate. Each semiconductor chip is bonded to a predetermined circuit pattern of the insulated circuit substrate.

For bonding the insulated circuit substrate including the semiconductor chips to the base substrate, a positioning jig that has a frame shape with an opening is used. Such a positioning jig is placed on the base substrate, and solder and the insulated circuit substrate are placed on the base substrate through the opening. Then, a heat treatment is carried out to melt the solder in order to bond the base substrate and the insulated circuit substrate together (for example, see Japanese Laid-open Patent Publication No. 2021-90030).

The opening of the positioning jig is formed larger in size than the insulated circuit substrate, considering the tolerance for the external dimensions of the insulated circuit substrate. When the insulated circuit substrate is placed via the solder on the base substrate using such a positioning jig and a heat treatment is carried out, the insulated circuit substrate may move on the molten solder in the opening of the positioning jig. This leads to misalignment of the insulated circuit substrate (and circuit patterns) with respect to a predetermined position on the base substrate.

### SUMMARY OF THE INVENTION

According to one aspect, there is provided a semiconductor device manufacturing method, including: preparing a semiconductor unit including a semiconductor chip and a substrate to which the semiconductor chip is bonded, and a base substrate having a unit area on a front surface thereof, the unit area being where the substrate of the semiconductor unit is to be disposed; forming a regulating member on the substrate such that the regulating member protrudes from a front surface of the substrate; arranging the semiconductor unit in the unit area via a bonding member through an opening area of a positioning jig placed on the front surface of the base substrate, the opening area defining the unit area; setting a regulating jig having a first end, a second end opposite to the first end, and regulating parts between the first end and the second end, on the positioning jig such that the regulating parts are positioned on sides of the regulating member and the first end and the second end of the regulating jig are respectively positioned on respective opposite sides of an opening edge of the opening area; and heating the base substrate, the bonding member, and the substrate to bond the substrate to the base substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a plan view of a semiconductor unit provided in the semiconductor device according to the first embodiment;

FIG. 3 is a sectional view of the semiconductor device according to the first embodiment;

FIG. 4 is a flowchart illustrating a semiconductor device manufacturing method according to the first embodiment;

FIG. 5 is a side view of a semiconductor unit manufactured in a unit manufacturing step in the semiconductor device manufacturing method according to the first embodiment;

FIG. 6 is a plan view of the semiconductor unit manufactured in the unit manufacturing step in the semiconductor device manufacturing method according to the first embodiment;

FIG. 7 is a plan view illustrating a bonding step (setting of positioning jig) in the semiconductor device manufacturing method according to the first embodiment;

FIG. 8 is an enlarged plan view of a main part of the bonding step (setting of positioning jig) in the semiconductor device manufacturing method according to the first embodiment;

FIG. 9 is a sectional view illustrating the bonding step (setting of positioning jig) in the semiconductor device manufacturing method according to the first embodiment;

FIG. 10 is a plan view illustrating the bonding step (arrangement of semiconductor unit) in the semiconductor device manufacturing method according to the first embodiment;

FIG. 11 is a sectional view illustrating the bonding step (arrangement of semiconductor unit) in the semiconductor device manufacturing method according to the first embodiment;

FIG. 12 is a plan view illustrating the bonding step (setting of regulating jig) in the semiconductor device manufacturing method according to the first embodiment;

FIG. 13 is a perspective view of the rear surface of a main part of a regulating jig that is used in the bonding step in the semiconductor device manufacturing method according to the first embodiment;

FIG. 14 is a sectional view (part 1) illustrating the bonding step (setting of regulating jig) in the semiconductor device manufacturing method according to the first embodiment;

FIGS. 15A and 15B are sectional views (part 2) illustrating the bonding step (setting of regulating jig) in the semiconductor device manufacturing method according to the first embodiment;

FIG. 16 is a sectional view (part 1) illustrating the bonding step (setting of regulating jig) in the semiconductor device manufacturing method according to the first embodiment (modification example 1-1);

FIG. 17 is a sectional view (part 2) illustrating the bonding step (setting of regulating jig) in the semiconductor device manufacturing method according to the first embodiment (modification example 1-1);

FIGS. 18A and 18B illustrate a semiconductor unit provided in the semiconductor device according to the first embodiment (modification example 1-2);

FIG. 19 is a plan view of a semiconductor unit that has a regulating member formed in a regulating member forming step in a semiconductor device manufacturing method according to a second embodiment;

FIG. 20 is a side view of the semiconductor unit that has the regulating member formed in the regulating member forming step in the semiconductor device manufacturing method according to the second embodiment;

FIG. 21 is a plan view of a main part of a bonding step (setting of positioning jig and arrangement of semiconductor unit) in the semiconductor device manufacturing method according to the second embodiment;

FIG. 22 is a side view of a main part of the bonding step (setting of positioning jig and arrangement of semiconductor unit) in the semiconductor device manufacturing method according to the second embodiment;

FIG. 23 is a plan view illustrating the bonding step (setting of regulating jig) in the semiconductor device manufacturing method according to the second embodiment;

FIG. 24 is a side view illustrating the bonding step (setting of regulating jig) in the semiconductor device manufacturing method according to the second embodiment;

FIG. 25 is a plan view illustrating the bonding step (heating) in the semiconductor device manufacturing method according to the second embodiment;

FIG. 26 is a plan view illustrating the bonding step (heating) in the semiconductor device manufacturing method according to the second embodiment (modification example 2-1);

FIG. 27 is a plan view illustrating the bonding step (heating) in the semiconductor device manufacturing method according to the second embodiment (modification example 2-2);

FIG. 28 is a plan view of a semiconductor unit having a regulating member and a reference member formed in a regulating member forming step in a semiconductor device manufacturing method according to a third embodiment;

FIG. 29 is a side view of the semiconductor unit having the regulating member and reference member formed in the regulating member forming step in the semiconductor device manufacturing method according to the third embodiment;

FIG. 30 is a plan view of a main part of a bonding step (setting of positioning jig and arrangement of semiconductor unit) in the semiconductor device manufacturing method according to the third embodiment;

FIG. 31 is a plan view illustrating the bonding step (setting of regulating jig) in the semiconductor device manufacturing method according to the third embodiment; and

FIG. 32 is a plan view illustrating the bonding step (heating) in the semiconductor device manufacturing method according to the third embodiment.

### DETAILED DESCRIPTION OF THE INVENTION

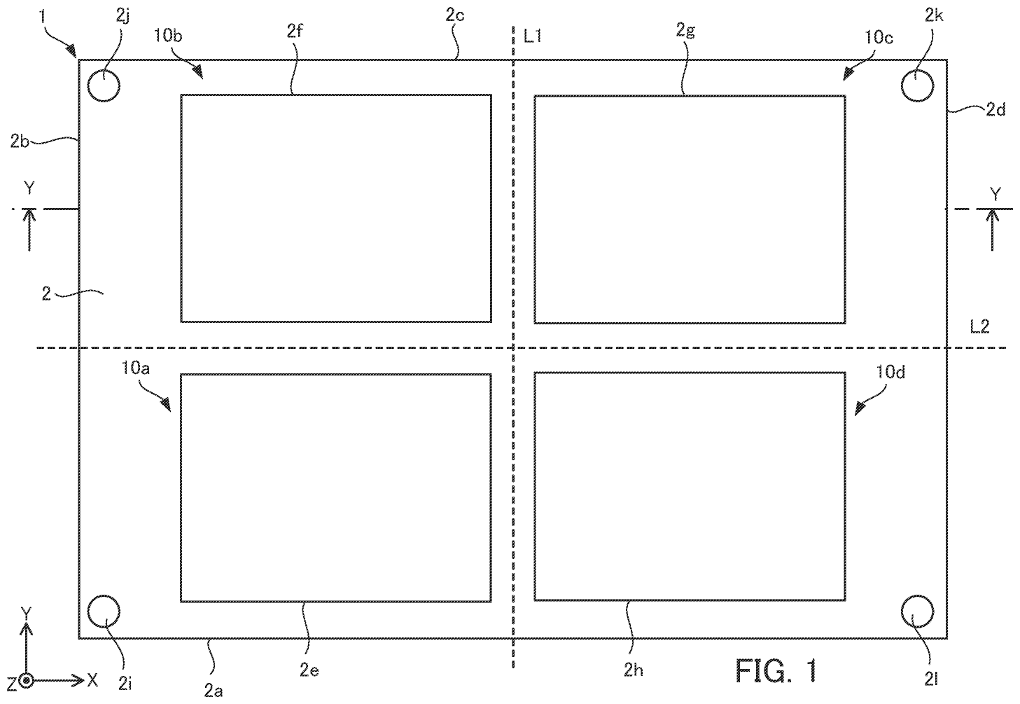

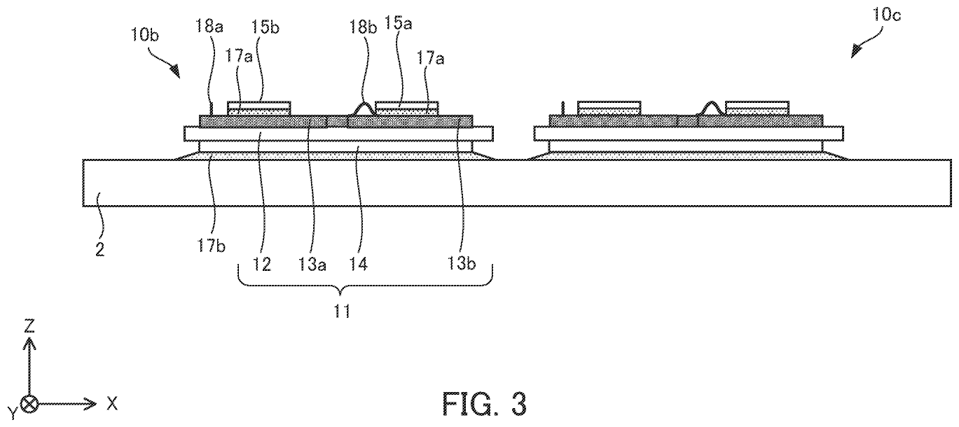

Hereinafter, some embodiments will be described with reference to the accompanying drawings. In the following description, the terms “front surface” and “top surface” refer to the X-Y surface facing upward (the +Z direction) in a semiconductor device of FIGS. 1 and 3. Similarly, the term “up” refers to an upward direction (+Z direction) in the semiconductor device of FIGS. 1 and 3. The terms “rear surface” and “bottom surface” refer to the X-Y surface facing downward (the −Z direction) in the semiconductor device of FIGS. 1 and 3. Similarly, the term “down” refers to a downward direction (−Z direction) in the semiconductor device of FIGS. 1 and 3. The term “higher level” refers to an upper position (in the +Z direction) in the semiconductor device of FIGS. 1 and 3. Similarly, the term “lower level” refers to a lower position (in the −Z direction) in the semiconductor device of FIGS. 1 and 3. The terms “front surface,” “top surface,” “up,” “rear surface,” “bottom surface,” “down,” and “side surface” are used for convenience to describe relative positional relationship, and do not limit the technical ideas of the embodiments. For example, the terms “up” and “down” are not always related to the vertical directions to the ground. That is, the “up” and “down” directions are not limited to the gravity direction. In addition, in the following description, the term “principal component” refers to a component contained at a volume ratio of 80 vol % or more.

### First Embodiment

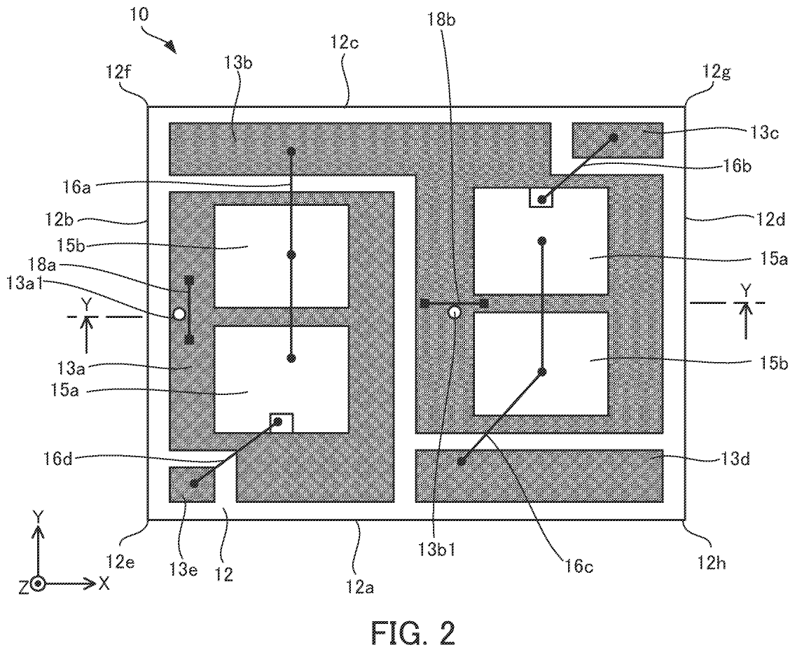

A semiconductor device 1 according to a first embodiment will be described with reference to FIGS. 1 to 3. FIG. 1 is a plan view of the semiconductor device according to the first embodiment. FIG. 2 is a plan view of a semiconductor unit provided in the semiconductor device according to the first embodiment. FIG. 3 is a sectional view of the semiconductor device according to the first embodiment. In this connection, the illustration of semiconductor units 10a to 10d is omitted in the semiconductor device 1 of FIG. 1. In addition, FIG. 3 is a sectional view taken along the dash-dotted line Y-Y of FIG. 1 (and FIG. 2). In this connection, the dash-dotted line Y-Y of FIG. 2 passes through the center of each short side 12b and 12d of an insulating plate 12.

The semiconductor device 1 includes a base substrate 2 and the semiconductor units 10a to 10d bonded to the base substrate 2. In the following description, the semiconductor units 10a to 10d are collectively referred to as “semiconductor units 10” and individually as “semiconductor unit 10” when the distinction among them is not needed.

The base substrate 2 is rectangular (oblong) in plan view. The base substrate 2 has a base long side 2a, base short side 2b, base long side 2c, and base short side 2d that surround the four sides thereof. In the present embodiment, it is assumed that the base substrate 2 has an oblong shape with the long sides and short sides as an example of the rectangular shape. Alternatively, the base substrate 2 may be square. Fastening holes 2i to 2l are formed at the four corners of the base substrate 2, respectively. The base substrate 2 is attached to a desired position via screws through these fastening holes 2i to 2l. In addition, the corners of the base substrate 2 may be rounded or chamfered. The base substrate 2 is made of a metal with high thermal conductivity. Examples of the metal include aluminum, magnesium, iron, silver, copper, and an alloy containing at least one of these. Plating may be performed on the surface of the base substrate 2 to improve its corrosion resistance. Examples of the plating material used here include nickel, a nickel-phosphorus alloy, and a nickel-boron alloy. In FIG. 1, center lines L1 and L2 respectively passing through the centers of the base long sides 2a and 2c and the centers of the base short sides 2b and 2d of the base substrate 2 are represented as dashed lines. Disposition areas 2e to 2h (unit areas) are set in the divided regions of the front surface of the base substrate 2 divided by the center lines L1 and L2, and one semiconductor unit 10 is disposed in each disposition area 2e to 2h. In this connection, the present embodiment describes, as an example, the case where the semiconductor units 10 are arranged in two rows and two columns on the base substrate 2. Alternatively, the semiconductor units 10 may be arranged in one row. In addition, the number of semiconductor units 10 is not limited to four but may be one or greater. The semiconductor units 10 may be arranged in n rows and m columns according to the number of semiconductor units 10.

The semiconductor unit 10 includes an insulated circuit substrate 11 and semiconductor chips 15a and 15b. In addition, the insulated circuit substrate 11 and semiconductor chips 15a and 15b are wired, as appropriate, with wires 16a to 16d.

The insulated circuit substrate 11 is rectangular in plan view. The insulated circuit substrate 11 includes an insulating plate 12, a plurality of circuit patterns 13a to 13d formed on the front surface of the insulating plate 12, and a metal plate 14 formed on the rear surface of the insulating plate 12. The plurality of circuit patterns 13a to 13d and metal plate 14 have outer shapes smaller than the insulating plate 12 in plan view and are formed inside the insulating plate 12. The shapes and quantity of the plurality of circuit patterns 13a to 13d are just an example.

The insulating plate 12 is rectangular (oblong) in plan view. The corners 12e to 12h of the insulating plate 12 may be chamfered or rounded, for example. The insulating plate 12 has a long side 12a, short side 12b, long side 12c, and short side 12d that surround the four sides thereof and that form the outer periphery thereof. In addition, the corner 12e is formed by the long side 12a and short side 12b. The corner 12f is formed by the short side 12b and long side 12c. The corner 12g is formed by the long side 12c and short side 12d. The corner 12h is formed by the short side 12d and long side 12a. The present embodiment uses the insulating plate 12 that has an oblong shape with the long sides and short sides as an example of the rectangular shape. Alternatively, the insulating plate 12 may be square. The insulating plate 12 is made of ceramics with high thermal conductivity. For example, the ceramics are made from materials containing aluminum oxide, aluminum nitride, or silicon nitride as a principal component. In addition, the thickness of the insulating plate 12 is in the range of 0.2 mm to 2.0 mm, inclusive.

The circuit patterns 13a to 13e are formed on the entire surface of the insulating plate 12 except the edge portion thereof. The thicknesses of the circuit patterns 13a to 13e are in the range of 0.1 mm to 2.0 mm, inclusive. The circuit patterns 13a to 13e are made of a metal with high electrical conductivity. Examples of the metal include copper, aluminum, and an alloy containing at least one of these. Plating may be performed on the surfaces of the circuit patterns 13a to 13e to improve their corrosion resistance. Examples of the plating material used here include nickel, a nickel-phosphorus alloy, and a nickel-boron alloy. In this connection, the circuit patterns 13a to 13e are formed by forming a metal plate on the front surface of the insulating plate 12 and performing an etching process or another on the metal plate. Alternatively, the circuit patterns 13a to 13e are cut out of a metal plate in advance and are then press-bonded to the front surface of the insulating plate 12. In this connection, these circuit patterns 13a to 13e are just an example. The quantity, shapes, sizes, and others of the circuit patterns may desirably be determined according to necessity.

The circuit pattern 13a is rectangular in plan view. More specifically, the circuit pattern 13a is formed along the long side 12a and short side 12b of the insulating plate 12 on the side of the insulating plate 12 where the long side 12a is positioned, and extends toward the long side 12c extending in the X direction. In addition, the end of the circuit pattern 13a in the Y direction is positioned closer to the long side 12c and has a gap to the long side 12c. The circuit pattern 13a has a rectangular notch area in the vicinity of the corner 12e formed by the long side 12a and short side 12b. In addition, a lead frame for positive electrode is bonded to the circuit pattern 13a.

In the circuit pattern 13a, a regulating marker 13a1 is formed on the center line (the dash-dotted line Y-Y) of the insulating plate 12 on the side where the short side 12b of the insulating plate 12 is positioned. For example, the regulating marker 13a1 is a micropore formed in the circuit pattern 13a. The regulating marker 13a1 is used as a mark for arranging a regulating member 18a. Therefore, the regulating member 18a is formed in the vicinity of the regulating marker 13a1. The regulating member 18a is a wire, for example, and has an arched shape to connect certain two points on the circuit pattern 13a. The regulating member 18a is arranged in parallel to the short side 12b (±Y directions) on the side of the circuit pattern 13a where the short side 12b of the insulating plate 12 is positioned so as to extend over the center line (the dash-dotted line Y-Y). The regulating member 18a in the arched shape protrudes from the circuit pattern 13a. The height from the circuit pattern 13a to the highest point of the regulating member 18a in the arched shape is approximately equal to the heights of the later-described semiconductor chips 15a and 15b measured from the circuit pattern 13a, for example. In the present embodiment, the height to the highest point of the regulating member 18a is lower than the heights of the semiconductor chips 15a and 15b measured from the circuit pattern 13a. The regulating member 18a is made of the same material as the later-described wires 16a to 16d.

The circuit pattern 13b has an approximately L shape with a corner positioned in the vicinity of the corner 12g in plan view. That is, the circuit pattern 13b is formed along the long side 12c and short side 12d of the insulating plate 12 on the side of the insulating plate 12 where the long side 12c is positioned. A portion of the circuit pattern 13b extending in the −X direction as seen from the corner 12g is positioned between the circuit pattern 13a and the long side 12c. In addition, a portion of the circuit pattern 13b extending in the −Y direction as seen from the corner 12g is positioned between the circuit pattern 13a and the short side 12d. In addition, the end of the portion of the circuit pattern 13b extending in the −Y direction is positioned closer to the long side 12a and has a gap to the long side 12a. In addition, the circuit pattern 13b has a rectangular notch area in the vicinity of the corner 12g formed by the long side 12c and short side 12d. In addition, a lead frame for output is bonded to the circuit pattern 13b.

In the circuit pattern 13b, a regulating marker 13b1 is formed on the center line (the dash-dotted line Y-Y) of the insulating plate 12 on the side where the short side 12b of the insulating plate 12 is positioned. The regulating marker 13b1 plays the same role as the regulating marker 13a1 and is formed in the circuit pattern 13b in the same manner. Therefore, a regulating member 18b is arranged in the vicinity of the regulating marker 13b1. The regulating member 18b is a wire, for example, and has an arched shape to connect certain two points on the circuit pattern 13b. The regulating member 18b is arranged in parallel to the long side 12a (±X directions). The regulating member 18b in the arched shape protrudes from the circuit pattern 13b as well. The height from the circuit pattern 13b to the highest point of the regulating member 18b in the arched shape is approximately equal to the heights of the semiconductor chips 15a and 15b measured from the circuit pattern 13b. In the present embodiment, the height to the highest point of the regulating member 18b is lower than the heights of the semiconductor chips 15a and 15b measured from the circuit pattern 13b. In the present embodiment, the regulating member 18b is made of the same material as the regulating member 18a and has the same diameter and the same height as the regulating member 18a.

The circuit pattern 13c is rectangular in plan view. The circuit pattern 13c is formed in the vicinity of the corner 12g formed by the long side 12c and short side 12d of the insulating plate 12. That is, the circuit pattern 13c is positioned in the notch area of the circuit pattern 13b.

The circuit pattern 13d has an I shape in plan view. The circuit pattern 13d is formed along the long side 12a and short side 12d of the insulating plate 12 on the side of the insulating plate 12 where the long side 12a is positioned. That is, the circuit pattern 13d is positioned between the end of the portion of the circuit pattern 13b extending in the −Y direction and the long side 12a. In addition, a lead frame for negative electrode is bonded to the circuit pattern 13d.

The circuit pattern 13e is rectangular in plan view. The circuit pattern 13e is formed in the vicinity of the corner 12e formed by the long side 12a and short side 12b of the insulating plate 12. That is, the circuit pattern 13e is positioned in the notch area of the circuit pattern 13a.

The shape and location of each circuit pattern in the first embodiment are not limited to those described above but may be changed.

The metal plate 14 is rectangular in plan view. The corners of the metal plate 14 may be chamfered or rounded, for example. The metal plate 14 is smaller in size than the insulating plate 12 and is formed on the entire rear surface of the insulating plate 12 except the edge portion thereof. The metal plate 14 is made of a metal with high thermal conductivity as a principal component. Examples of the metal include copper, aluminum, and an alloy containing at least one of these. In addition, the thickness of the metal plate 14 is in the range of 0.1 mm to 2.0 mm, inclusive. Plating may be performed on the surface of the metal plate to improve its corrosion resistance. Examples of the plating material used here include nickel, a nickel-phosphorus alloy, and a nickel-boron alloy.

As the insulated circuit substrate 11 configured as above, a direct copper bonding (DCB) substrate or an active metal brazed (AMB) substrate may be used, for example. The insulated circuit substrate 11 transfers heat generated by the later-described semiconductor chips 15a and 15b through the circuit patterns 13a and 13b, the insulating plate 12, and the metal plate 14 to the rear surface of the insulated circuit substrate 11 to dissipate the heat. Such an insulated circuit substrate 11 is bonded to each of the disposition areas 2e to 2h of the base substrate 2 using solder 17b (see FIG. 3). A lead-free solder is used as the solder 17b. For example, the lead-free solder contains any one of a tin-silver-copper alloy, a tin-zinc-bismuth alloy, a tin-copper alloy, and a tin-silver-indium-bismuth alloy as a principal component. In addition, the solder 17b may contain an additive. Examples of the additive include nickel, germanium, cobalt, antimony, and silicon. The solder 17b containing the additive exhibits improved wettability, gloss, and bond strength, which results in an improvement in the reliability.

The semiconductor chips 15a and 15b are made of silicon, silicon carbide, or gallium nitride as a principal component. The semiconductor chips 15a include switching elements. Each switching element is an IGBT or a power MOSFET, for example. In the case where a semiconductor chip 15a is an IGBT, the semiconductor chip 15a has a collector electrode serving as a main electrode on the rear surface thereof and has a gate electrode and an emitter electrode serving as a main electrode on the front surface thereof. In the case where a semiconductor chip 15a is a power MOSFET, the semiconductor chip 15a has a drain electrode serving as a main electrode on the rear surface thereof and has a gate electrode and a source electrode serving as a main electrode on the front surface thereof.

The semiconductor chips 15b include diode elements. Each diode element is a free wheeling diode (FWD) such as a Schottky barrier diode (SBD) or a P-intrinsic-N (PiN) diode, for example. A semiconductor chip 15b of this type has a cathode electrode serving as a main electrode on the rear surface thereof and has an anode electrode serving as a main electrode on the front surface thereof.

The rear surfaces of the semiconductor chips 15a and 15b are bonded to the predetermined circuit patterns 13a and 13b using solder 17a (see FIG. 3). A lead-free solder is used as the solder 17a. For example, the lead-free solder contains any one of a tin-silver-copper alloy, a tin-zinc-bismuth alloy, a tin-copper alloy, and a tin-silver-indium-bismuth alloy as a principal component. In addition, the solder 17a may contain an additive. Examples of the additive include nickel, germanium, cobalt, and silicon. The solder 17a containing the additive exhibits improved wettability, gloss, and bond strength, which results in an improvement in the reliability. A sintered metal may be used instead of the solder 17a. In addition, the thicknesses of the semiconductor chips 15a and 15b are approximately 100 μm or more, for example.

The wires 16a to 16d are made of a material with high electrical conductivity. Examples of the material include gold, silver, copper, aluminum, and an alloy containing at least one of these. In addition, the diameters of the wires 16b and 16d are in the range of 110 μm to 400 μm, inclusive, for example. The diameters of the wires 16a and 16c are in the range of 300 μm to 500 μm, inclusive, for example.

The wire 16a directly connects the main electrodes on the front surfaces of the semiconductor chips 15a and 15b on the circuit pattern 13a and the circuit pattern 13b. The wire 16b directly connects the control electrode on the front surface of the semiconductor chip 15a on the circuit pattern 13b and the circuit pattern 13c. The wire 16c directly connects the main electrodes on the front surfaces of the semiconductor chips 15a and 15b on the circuit pattern 13b and the circuit pattern 13d. The wire 16d directly connects the control electrode on the front surface of the semiconductor chip 15a on the circuit pattern 13a and the circuit pattern 13e.

By bonding the semiconductor units 10a to 10d configured as above to the base substrate 2, the semiconductor device 1 is obtained. The semiconductor device 1 may further include lead frames for control, positive electrode, negative electrode, and output (not illustrated). In addition, in the semiconductor device 1, the base substrate 2, semiconductor units 10, and lead frames may be housed in a case, and the inside of the case may be sealed with a sealing material. At this time, external connection terminals included in the lead frames extend out of the case.

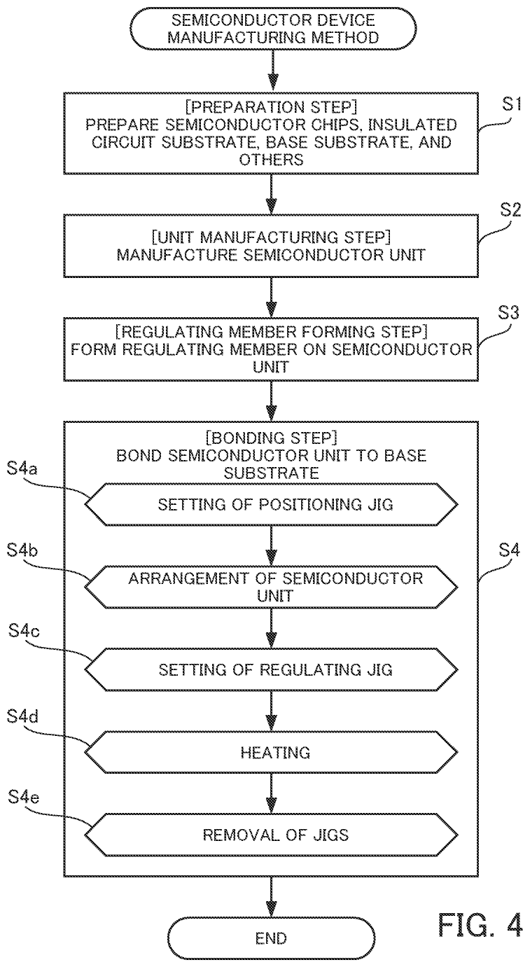

A method of manufacturing the above-described semiconductor device 1 will now be described with reference to FIG. 4. FIG. 4 is a flowchart illustrating a semiconductor device manufacturing method according to the first embodiment. First, a preparation step of preparing the semiconductor chips 15a and 15b, insulated circuit substrate 11, base substrate 2, and others is executed (step S1). In the preparation step, the components of the semiconductor device 1 are prepared. In addition to these, the lead frames, case, sealing material, and wires may be prepared.

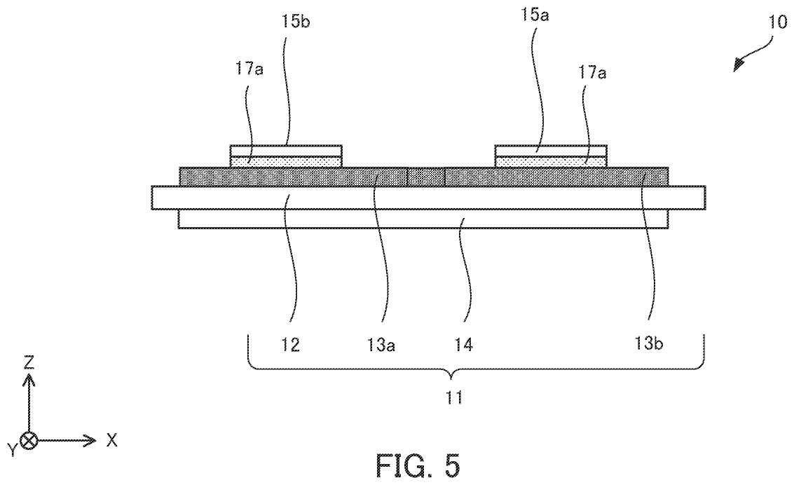

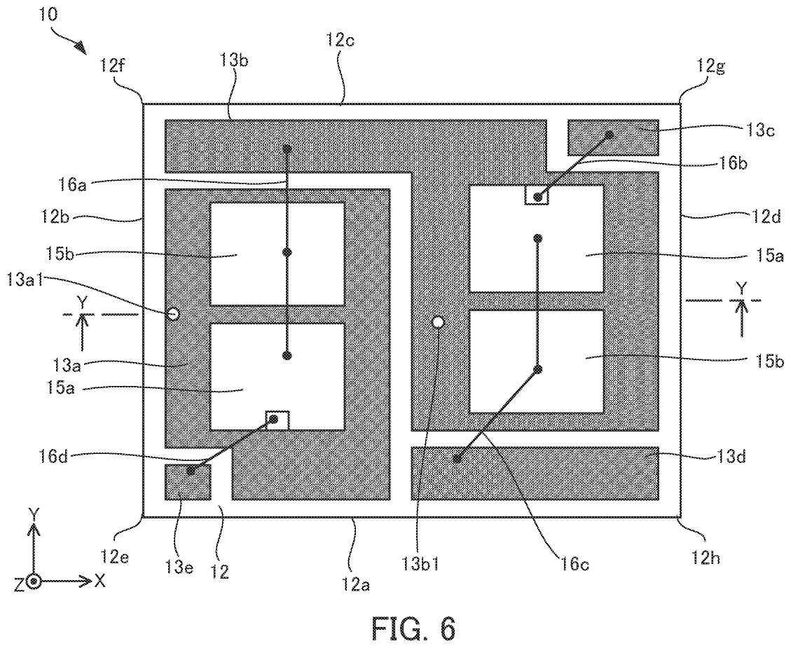

Then, a unit manufacturing step of manufacturing the semiconductor unit 10 is executed (step S2). The semiconductor unit 10 manufactured in the unit manufacturing step will be described with reference to FIGS. 5 and 6. FIG. 5 is a side view of a semiconductor unit manufactured in the unit manufacturing step in the semiconductor device manufacturing method according to the first embodiment. FIG. 6 is a plan view of the semiconductor unit manufactured in the unit manufacturing step in the semiconductor device manufacturing method according to the first embodiment. In this connection, FIG. 5 is a sectional view taken along the dash-dotted line Y-Y of FIG. 6.

The semiconductor unit 10 manufactured in the unit manufacturing step includes the insulated circuit substrate 11 and semiconductor chips 15a and 15b as illustrated in FIGS. 5 and 6. The insulated circuit substrate 11 and semiconductor chips 15a and 15b are wired as appropriate with the wires 16a to 16d.

Then, a regulating member forming step of forming the regulating members 18a and 18b on the semiconductor unit 10 is executed (step S3). In the regulating member forming step, the regulating member 18b is arranged in parallel to the long side 12a (±X directions) in the vicinity of the regulating marker 13b1 formed in the circuit pattern 13b of the semiconductor unit 10 illustrated in FIGS. 5 and 6, with the regulating marker 13b1 as a mark. Similarly, the regulating member 18a is arranged in parallel to the short side 12b (±Y directions) in the vicinity of the regulating marker 13a1 formed in the circuit pattern 13a of the semiconductor unit 10, with the regulating marker 13a1 as a mark. By doing so, the semiconductor unit 10 having the regulating members 18a and 18b formed thereon as illustrated in FIGS. 2 and 3 is obtained. In this connection, this step may be executed simultaneously with the above-described unit manufacturing step (step S2).

Then, a bonding step of bonding the semiconductor unit 10 obtained at step S3 to the base substrate 2 is executed (step S4). The bonding step in step S4 includes steps S4a to S4e.

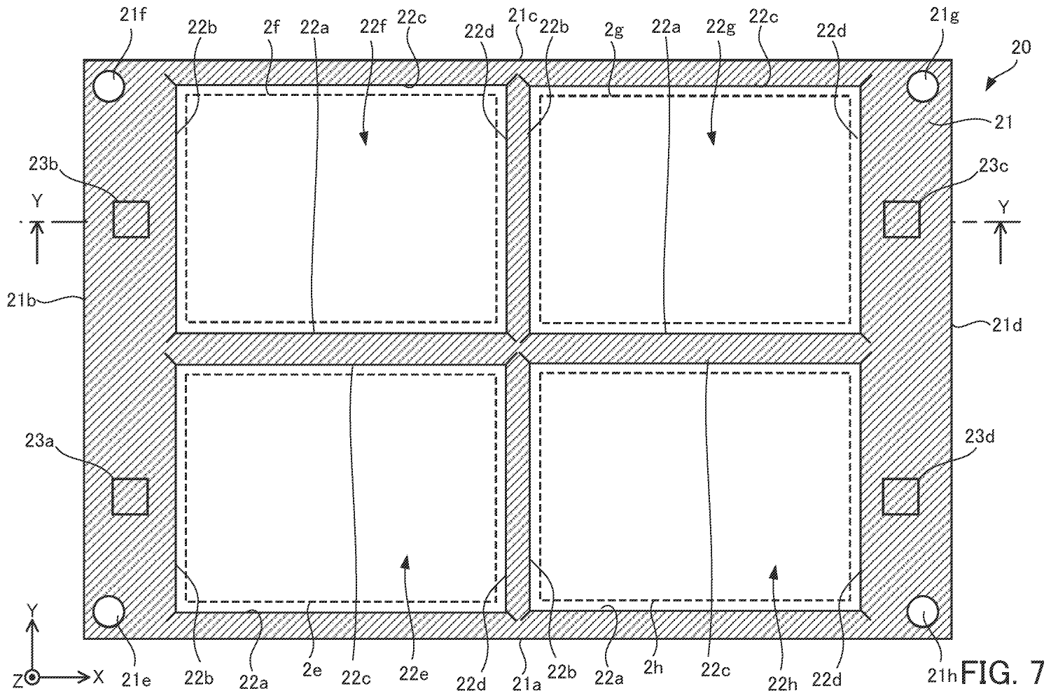

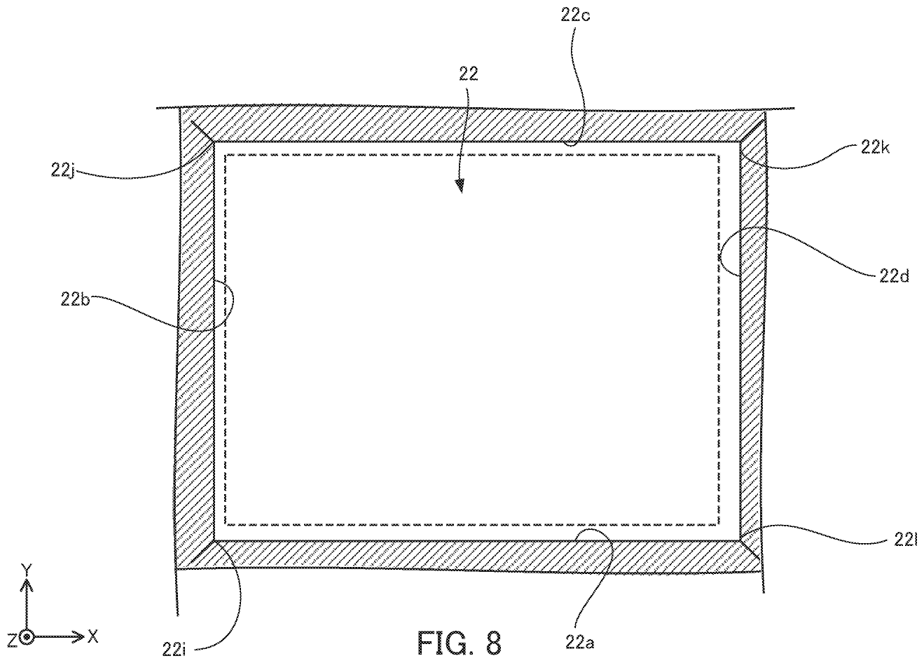

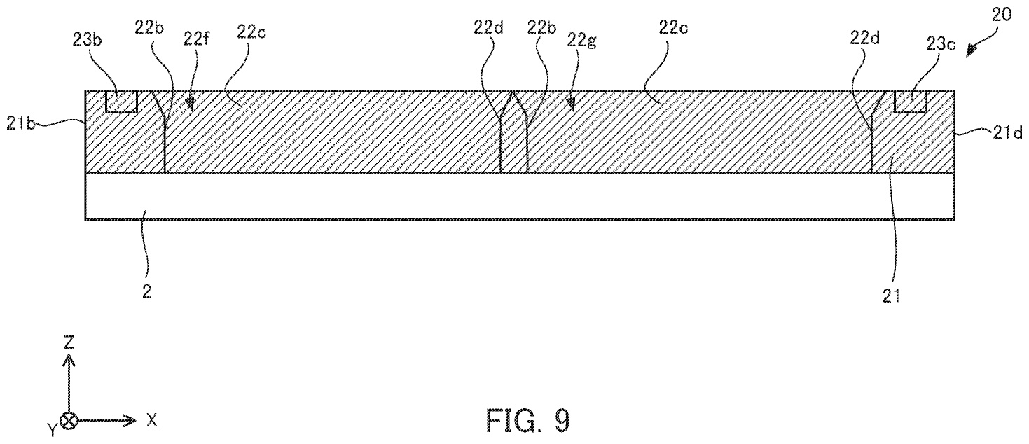

First, a positioning jig 20 is set on the front surface of the base substrate 2 (step S4a). This step S4a will now be described with reference to FIGS. 7 to 9. FIG. 7 is a plan view illustrating the bonding step (setting of positioning jig) in the semiconductor device manufacturing method according to the first embodiment. FIG. 8 is an enlarged plan view of a main part of the bonding step (setting of positioning jig) in the semiconductor device manufacturing method according to the first embodiment. FIG. 9 is a sectional view illustrating the bonding step (setting of positioning jig) in the semiconductor device manufacturing method according to the first embodiment. In this connection, FIG. 9 is a sectional view taken along the dash-dotted line Y-Y of FIG. 7.

The positioning jig 20 is placed on the front surface of the base substrate 2 as illustrated in FIGS. 7 and 9. The positioning jig 20 is made of a material that has high thermal resistance and that is not wet by solder. For example, such a material is carbon or a metal having an oxide film formed on the surface thereof. The positioning jig 20 has a flat plate shape. In addition, the positioning jig 20 includes a frame member 21 having four openings 22e to 22h (opening areas) formed therein and therefore has a lattice pattern. In the following description, the openings 22e to 22h are collectively referred to as “openings 22” and individually as “opening 22” when the distinction among them is not needed. The opening 22 is an area surrounded by an opening long side 22a, opening short side 22b, opening long side 22c, and opening short side 22d of the opening edge, as illustrated in FIG. 8. In addition, an opening corner 22i is formed by the opening long side 22a and opening short side 22b. An opening corner 22j is formed by the opening short side 22b and opening long side 22c. An opening corner 22k is formed by the opening long side 22c and opening short side 22d. An opening corner 22l is formed by the opening short side 22d and opening long side 22a. The height (depth) of the opening 22 corresponds to the thickness of the frame member 21. The height of the opening 22 is greater than that of the semiconductor unit 10 (the total height including the height of a solder sheet 17b1). The area of the opening 22 in plan view may be equal to those of the disposition areas 2e to 2h of the base substrate 2 or may be a size larger than those of the disposition areas 2e to 2h. The openings 22 of the positioning jig 20 placed on the base substrate 2 demarcate the disposition areas 2e to 2h of the base substrate 2.

The frame member 21 has a jig long side 21a, jig short side 21b, jig long side 21c, and jig short side 21d that surround the four sides thereof. In this case, in the opening 22, the opening long side 22a corresponds to the jig long side 21a, the opening short side 22b to the jig short side 21b, the opening long side 22c to the jig long side 21c, and the opening short side 22d to the jig short side 21d. The outer periphery of the frame member 21 in plan view approximately matches the outer periphery of the front surface of the base substrate 2. The positioning jig 20 has through holes 21e to 21h respectively formed at the four corners thereof. When the positioning jig 20 is placed on the base substrate 2, the openings 22e to 22h correspond to the disposition areas 2e to 2h of the base substrate 2, respectively. In this connection, the opening 22 has a tapered opening edge in sectional view. When the later-described semiconductor units 10 are placed in the disposition areas 2e to 2h of the base substrate 2 through the openings 22, the tapering guides the semiconductor units 10 to the disposition areas 2e to 2h, so that the semiconductor units 10 are positioned properly.

In addition, the through holes 21e to 21h of the positioning jig 20 are aligned with the fastening holes 2i to 2l of the base substrate 2, respectively. By inserting predetermined pins in the through holes 21e to 21h and fastening holes 2i to 2l, for example, the positioning jig 20 is fixed to the base substrate 2.

Fixing holes 23a and 23d are formed in the front surface of the frame member 21 such that the openings 22e and 22h are positioned between the fixing holes 23a and 23d. In addition, the fixing holes 23a and 23d are positioned on the center line passing through the center of each opening short side 22b and 22d of the openings 22e and 22h. Similarly, fixing holes 23b and 23c are formed in the front surface of the frame member 21 such that the openings 22f and 22g are positioned between the fixing holes 23b and 23c. In addition, the fixing holes 23b and 23c are positioned on the center line passing through the center of each opening short side 22b and 22d of the openings 22f and 22g. The depths and areas of the fixing holes 23a to 23d may be set so that the fixing holes 23a to 23d are able to engage with later-described fixing projections 32. In addition, the shapes of the fixing holes 23a to 23d in plan view correspond to the shapes of the fixing projections 32 in plan view. Their shapes may be circular or rectangular, for example. As with the openings 22, each fixing hole 23a to 23d may have a tapered opening edge.

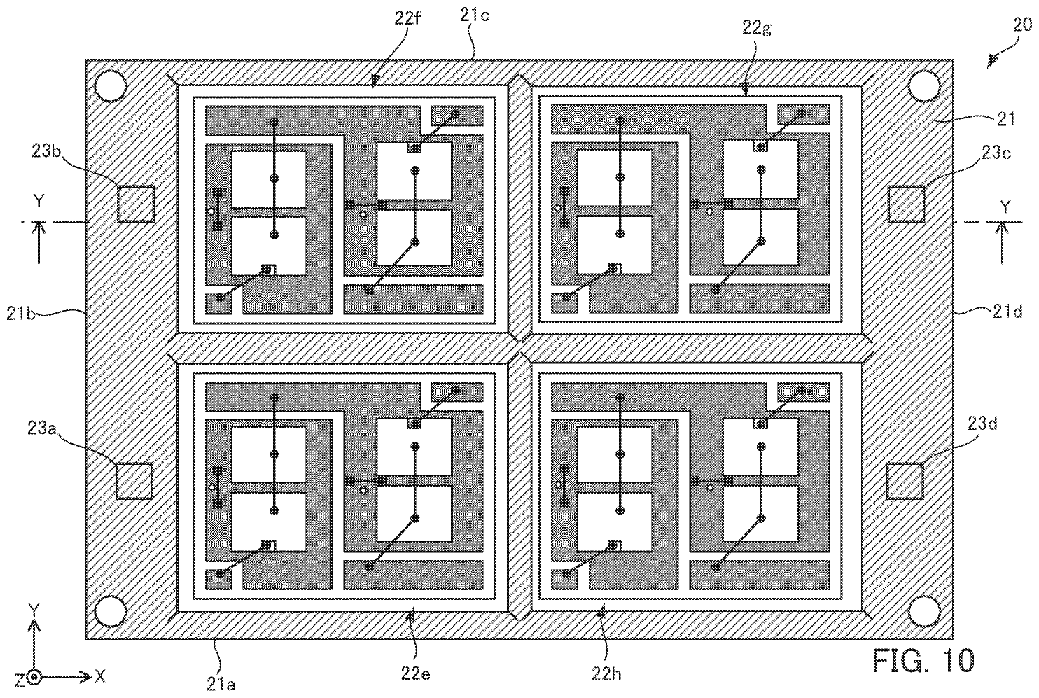

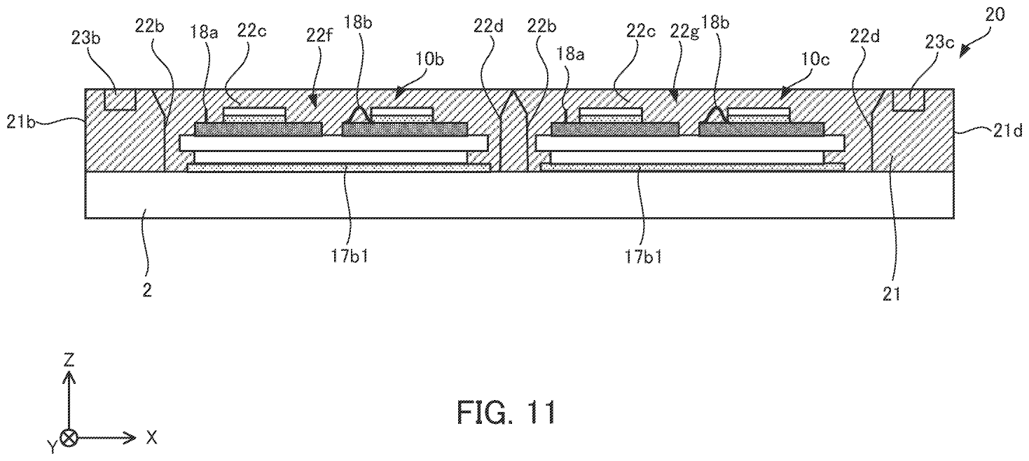

Then, the semiconductor unit 10 is disposed on the base substrate 2 using the positioning jig 20 (step S4b). This step S4b will be described with reference to FIGS. 10 and 11. FIG. 10 is a plan view illustrating the bonding step (arrangement of semiconductor unit) in the semiconductor device manufacturing method according to the first embodiment.

FIG. 11 is a sectional view illustrating the bonding step (arrangement of semiconductor unit) in the semiconductor device manufacturing method according to the first embodiment. In this connection, FIG. 11 is a sectional view taken along the dash-dotted line Y-Y of FIG. 10.

Solder sheets 17b1 are placed in the disposition areas 2e to 2h of the base substrate 2 through the openings 22e to 22h of the positioning jig 20 placed on the base substrate 2. The solder sheets 17b1 have the same composition as the above-described solder 17b. Then, the semiconductor units 10 are disposed on the solder sheets 17b1 in the disposition areas 2e to 2h of the base substrate 2 through the openings 22e to 22h of the positioning jig 20, as illustrated in FIGS. 10 and 11. At this time, the fixing holes 23a and 23d and regulating members 18b are on a straight line. The regulating members 18a are positioned such that their center points form the straight line with the fixing holes 23a and 23d and regulating members 18b. In addition, the fixing holes 23b and 23c and regulating members 18b are on a straight line. The regulating members 18a are positioned such that their center points form the straight line with the fixing holes 23b and 23c and regulating members 18b.

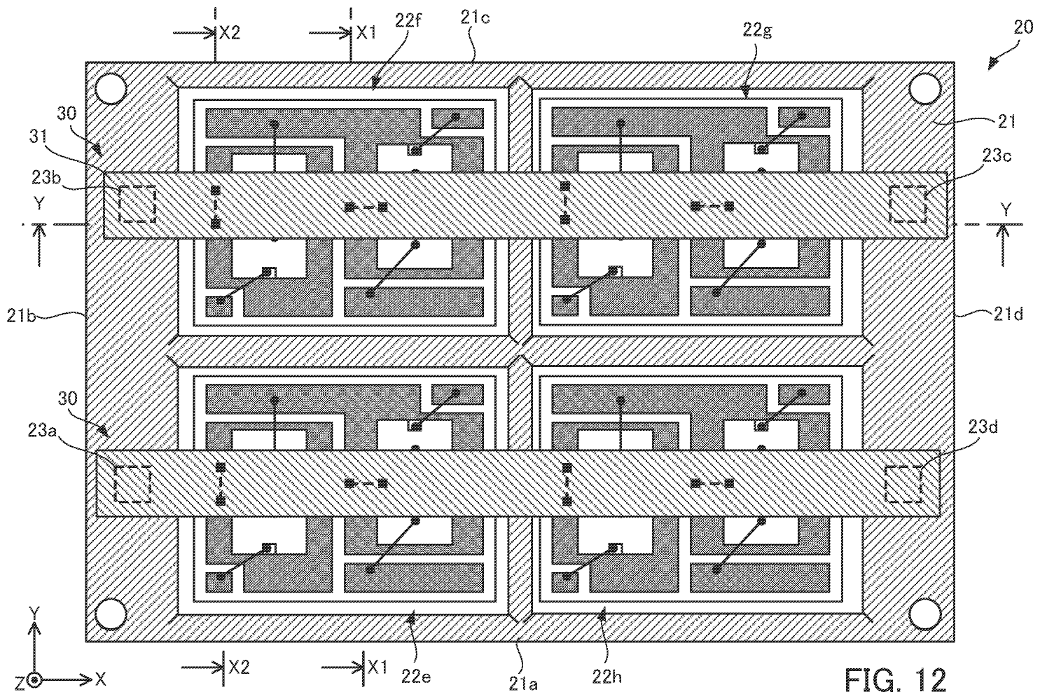

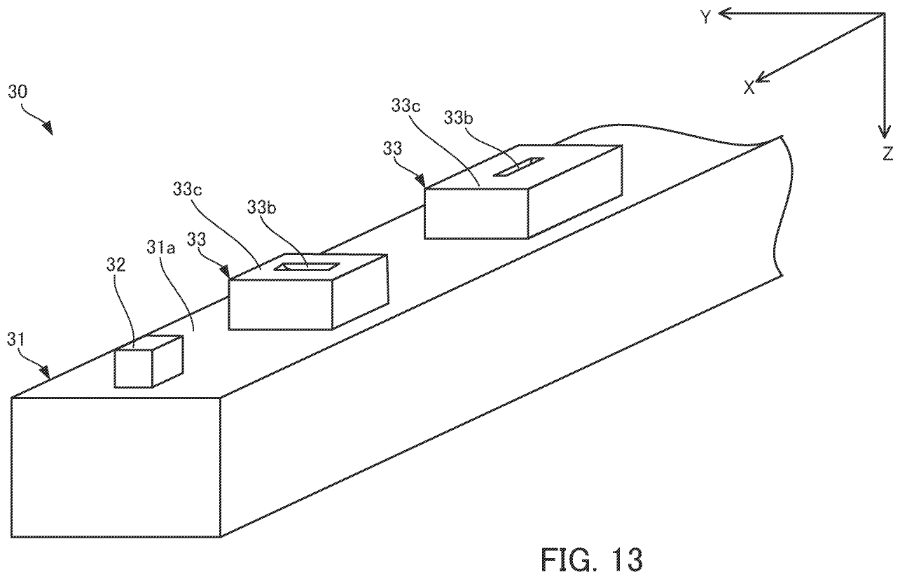

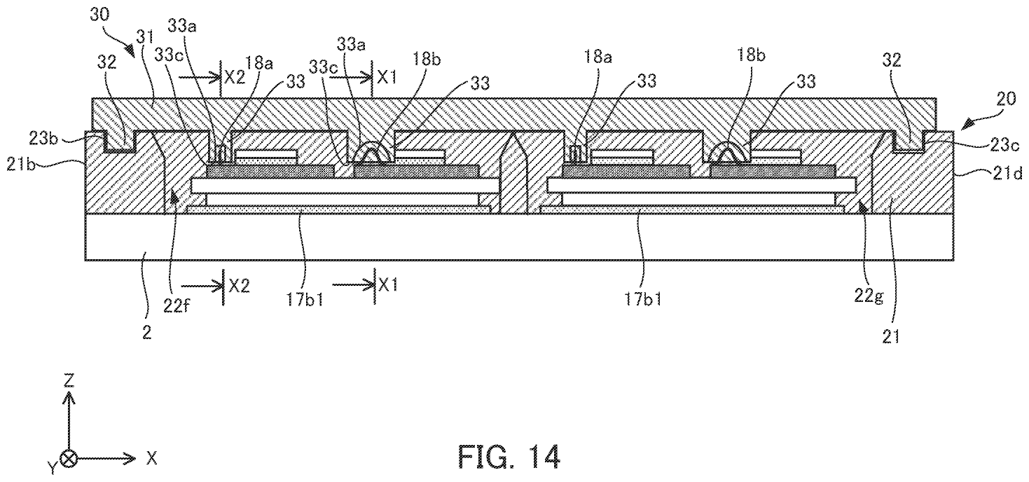

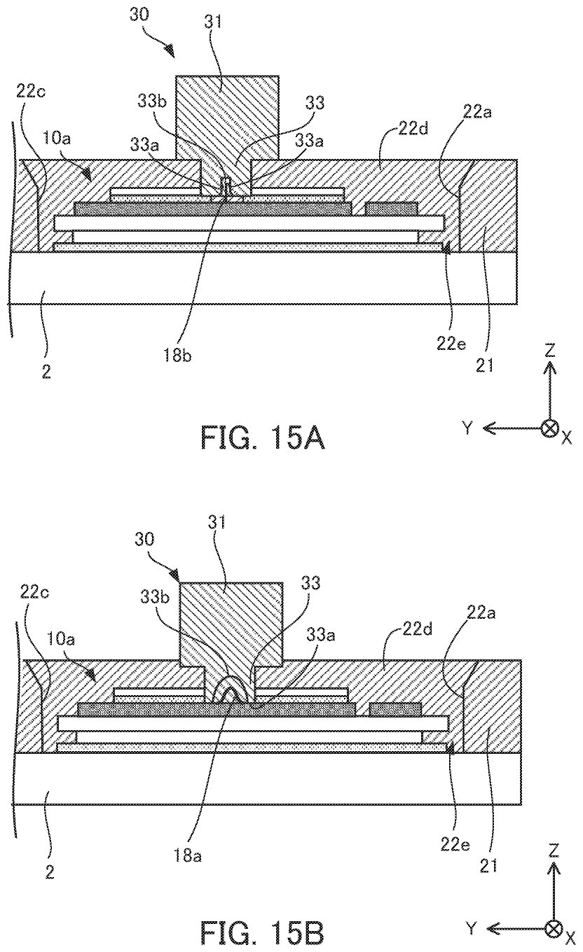

Then, regulating jigs are set on the positioning jig 20 (step S4c). This step S4c will be described with reference to FIGS. 12, 13, 14, 15A, and 15B. FIG. 12 is a plan view illustrating the bonding step (setting of regulating jig) in the semiconductor device manufacturing method according to the first embodiment. FIG. 13 is a perspective view of the rear surface of a main part of a regulating jig that is used in the bonding step in the semiconductor device manufacturing method according to the first embodiment. FIGS. 14, 15A and 15B are sectional views illustrating the bonding step (setting of regulating jig) in the semiconductor device manufacturing method according to the first embodiment. In this connection, FIG. 13 illustrates the rear surface of an end portion of a regulating jig 30. Here, hatching is not applied to the regulating jig 30. FIG. 14 is a sectional view taken along the dash-dotted line Y-Y of FIG. 12. FIGS. 15A and 15B are sectional views respectively taken along the dash-dotted lines X1-X1 and X2-X2 of FIGS. 12 and 14.

Regulating jigs 30 are placed on the positioning jig 20 in which the semiconductor units 10 are placed, as illustrated in FIGS. 12 and 14. At this time, the regulating jigs 30 are fixed to the positioning jig 20 by fixing parts (the fixing holes 23a to 23d of the positioning jig 20 and the later-described fixing projections 32). By doing so, the positions of the regulating jigs 30 in the X-direction and Y-direction with respect to the positioning jig 20 are fixed. Each regulating jig 30 includes a bridging portion 31, fixing projections 32, and regulating protrusions 33. In this connection, the regulating jigs 30 are made of the same material as the positioning jig 20. The bridging portion 31 has a columnar shape with a facing surface 31a. The facing surface 31a faces the front surface of the base substrate 2 when the regulating jig 30 is placed on the positioning jig 20. With such a facing surface 31a, the cross section of the bridging portion 31 perpendicular to the long-side direction thereof may be rectangular, triangular, or semicircular. Here, it is assumed as an example that the bridging portion 31 has a rectangular cross section (that is, a prismatic shape). The width (in the ±Y directions) of the facing surface 31a may be greater than the width of the regulating member 18a (arranged in the ±Y directions), for example. The length (in the ±X directions) of the facing surface 31a may be set so that the facing surface 31a extends over the openings 22f and 22g (or the openings 22e and 22h) and is placed on the front surface of the frame member 21.

The fixing projections 32 are formed at both ends of the facing surface 31a (one end and the other end of the bridging portion 31) such as to project from the facing surface 31a and to correspond to the fixing holes 23a and 23d or the fixing holes 23b and 23c. The sizes of the fixing projections 32 are set so that they are able to engage with the fixing holes 23a to 23d of the frame member 21 to achieve positioning in the X direction and Y direction. Therefore, when the regulating jig 30 is placed over the openings 22e and 22h of the positioning jig 20, the fixing projections 32 engage with the fixing holes 23a and 23d. Similarly, when the regulating jig 30 is placed over the openings 22f and 22g of the positioning jig 20, the fixing projections 32 engage with the fixing holes 23b and 23c.

The regulating protrusions 33 are formed on the facing surface 31a of the bridging portion 31 so as to protrude from the facing surface 31a. The regulating protrusions 33 are formed at such positions on the facing surface 31a that they correspond to the regulating members 18a and 18b when the regulating jig 30 is placed on the positioning jig 20. In addition, each regulating protrusion 33 may have a protrusion surface 33c so that, when the regulating jig 30 is placed on the positioning jig 20, the protrusion surface 33c comes closer to the insulated circuit substrate 11 (circuit pattern), as illustrated in FIG. 14. The shapes of the regulating protrusions 33 have a box shape, for example.

In addition, each protrusion surface 33c has a groove 33b formed therein. The grooves 33b are formed in the protrusion surfaces 33c such that their groove long-side directions are along the wiring directions of the regulating members 18a and 18b. More specifically, for the regulating member 18a, the groove long-side direction of a groove 33b is along the ±Y directions. For the regulating member 18b, the groove long-side direction of a groove 33b is along the ±X directions, as illustrated in FIG. 13. The depths (in the ±Z directions) of the grooves 33b may be set so that, when the regulating jig 30 is placed on the positioning jig 20, the regulating members 18a and 18b are able to enter the grooves 33b. In addition, with respect to the shapes of the grooves 33b, the grooves 33b may have a semicircular cross section in the groove long-side direction so as to correspond to the shapes of the top portions of the regulating members 18a and 18b.

Inside the groove 33b that the regulating member 18b enters, for example, regulating surfaces 33a (regulating parts) opposite to each other are provided in parallel to the groove long-side direction (±X directions), as illustrated in FIG. 15A. Inside the groove 33b that the regulating member 18a enters, regulating surfaces 33a opposite to each other are provided in parallel to the direction (±Y directions) perpendicular to the groove long-side direction (±X directions) of FIG. 15A, as illustrated in FIG. 15B. The regulating member 18b entering the groove 33b is positioned between the opposite regulating surfaces 33a. Note that FIG. 15B illustrates one of the opposite regulating surfaces 33a. The grooves 33b each may have a tapered opening edge. Therefore, when the regulating jig 30 is placed over the openings 22e and 22h of the positioning jig 20, the regulating members 18a and 18b enter the grooves 33b formed in the protrusion surfaces 33c of the regulating protrusions 33 (see FIGS. 14, 15A, and 15B). At this time, for example, each regulating member 18b entering the groove 33b is positioned between the opposite regulating surfaces 33a. The same applies to the regulating member 18a.

Then, the semiconductor units 10 placed on the base substrate 2 using the positioning jig 20 and the regulating jig 30 placed on the positioning jig 20 in the manner described above are heated (step S4d). When these are heated at a predetermined temperature, the solder sheets 17b1 are molten. As described earlier, the opening 22 of the positioning jig 20 is larger in area than the semiconductor unit 10 (insulated circuit substrate 11). Since the solder sheets 17b1 are molten, the semiconductor units 10 tend to move on the molten solder sheets 17b1.

Note that the regulating members 18a and 18b of the semiconductor units 10 enter the grooves 33b of the regulating jigs 30. In addition, the regulating jigs 30 are fixed to the positioning jig 20 by the fixing projections 32. Therefore, the movement of the semiconductor units 10 is restricted by the regulating members 18a and 18b and regulating jigs 30. Especially, the regulating members 18a restrict the movement of the semiconductor units 10 in the ±X directions, and the regulating members 18b restrict the movement of the semiconductor units 10 in the ±Y directions. Therefore, the positional shift of the semiconductor units 10 due to the melting of the solder sheets 17b1 is prevented. The molten solder sheets 17b1 are then solidified, so that the semiconductor units 10 are bonded to the base substrate 2 by the solder 17b. The semiconductor units 10 are bonded to the disposition areas 2e to 2h on the base substrate 2 with precision, without misalignment.

Then, the various jigs used are removed (step S4e). After the semiconductor units 10 are bonded to the base substrate 2, the regulating jigs 30 are removed. After that, the positioning jig 20 is removed. As a result, the semiconductor device 1 illustrated in FIGS. 1 and 3 is obtained. In this connection, after that, lead frames are attached to the semiconductor device 1, which is then housed in a case. Since the semiconductor units 10 are aligned with the disposition areas 2e to 2h of the base substrate 2 with precision, it is possible to bond the lead frames to the correct positions on the semiconductor units 10.

In the above-described method of manufacturing the semiconductor device 1, the components of the semiconductor device 1 are prepared, and the regulating members 18a and 18b are formed to protrude from the front surface of each insulated circuit substrate 11. Then, the semiconductor units 10 are placed in the disposition areas 2e to 2h via the solder sheets 17b1 through the openings 22e to 22h, which demarcate the disposition areas 2e to 2h, of the positioning jig 20 placed on the front surface of the base substrate 2. Then, the regulating jigs 30 each having one end, the other end, and grooves 33b that each have the opposite regulating surfaces 33a therein and that are formed between the one end and the other end are set on the positioning jig 20. At this time, each regulating member 18a and 18b entering the grooves 33b is positioned between the regulating surfaces 33a, and the one end and the other end of each regulating jig 30 are positioned on the opening edges of the openings 22e to 22h. Then, the base substrate 2, solder sheets 17b1, and insulated circuit substrates 11 are heated to bond the insulated circuit substrates 11 to the base substrate 2. The use of the regulating members 18a and 18b and the regulating jigs 30 enables bonding the insulated circuit substrates 11 to the disposition areas 2e to 2h on the base substrate 2 with precision, without misalignment. Therefore, it is possible to manufacture a semiconductor device with precision, including the bonding of lead frames to predetermined positions on the insulated circuit substrates 11.

The present embodiment describes, as an example, the case where the regulating members 18a and 18b (regulating markers 13a1 and 13b1) are formed on the center line parallel to the long sides 12a and 12c on the insulated circuit substrate 11. The positions of the regulating members 18a and 18b (regulating markers 13a1 and 13b1) are not limited thereto, but they may be formed at positions that do not impede the semiconductor chips 15a and 15b and wires 16a and 16b on the insulated circuit substrate 11. According to the positions of the regulating members 18a and 18b, the positions of the regulating jigs 30 (the positions of the fixing holes 23a to 23d) with respect to the positioning jig 20 are changed appropriately.

In addition, the movement of the semiconductor unit 10 in the ±X directions and in the ±Y directions is restricted by the regulating members 18a and 18b without fail. Only one of the regulating members 18a and 18b may be formed on the insulated circuit substrate 11. In this case, the movement of the semiconductor unit 10 is restricted to some extent since either the regulating member 18a or 18b enters the groove 33b of the regulating jig 30.

In addition, in the present embodiment, the regulating jigs 30 are placed on the positioning jig 20 such that the regulating jigs 30 extend over the openings 22e and 22h and over the openings 22f and 22g (in the ±X directions), respectively. The positions of the regulating jigs 30 are not limited thereto, but the regulating jigs 30 may be placed on the positioning jig 20 such that the regulating jigs 30 extend over the openings 22e and 22f and over the openings 22h and 22g (in the ±Y directions), respectively. Alternatively, the regulating jigs 30 may be provided for each opening 22 on the positioning jig 20 in the ±X directions or ±Y directions. Yet alternatively, a flat plate-shaped lid in which the regulating protrusions 33 and fixing projections 32 on the facing surfaces 31a of the regulating jigs 30 are formed may be used to cover the entire front surface of the positioning jig 20. Only by attaching the lid to the positioning jig 20, the regulating members 18a and 18b of the semiconductor units 10 enter the grooves 33b.

The following describes modification examples of the regulating jigs 30 and regulating members 18a and 18b that are used in the method of manufacturing the semiconductor device 1.

### Modification Example 1-1

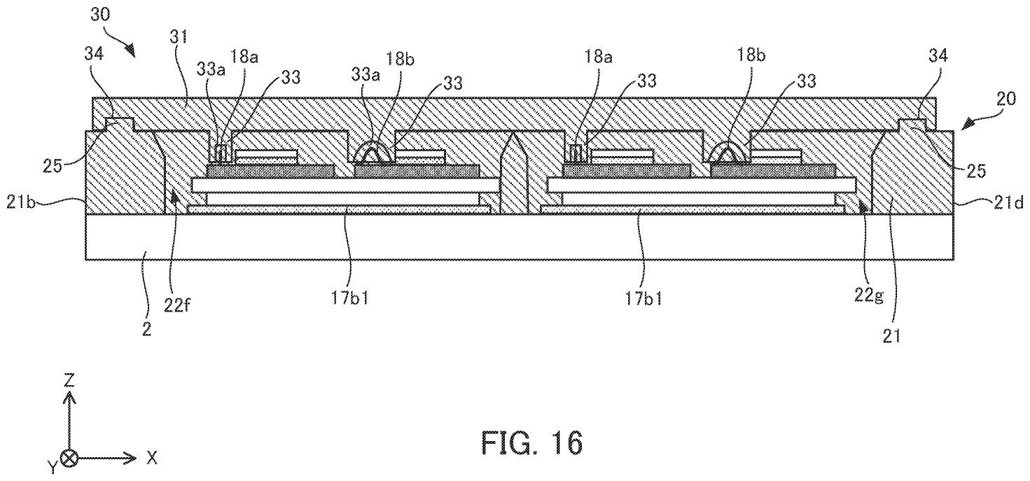

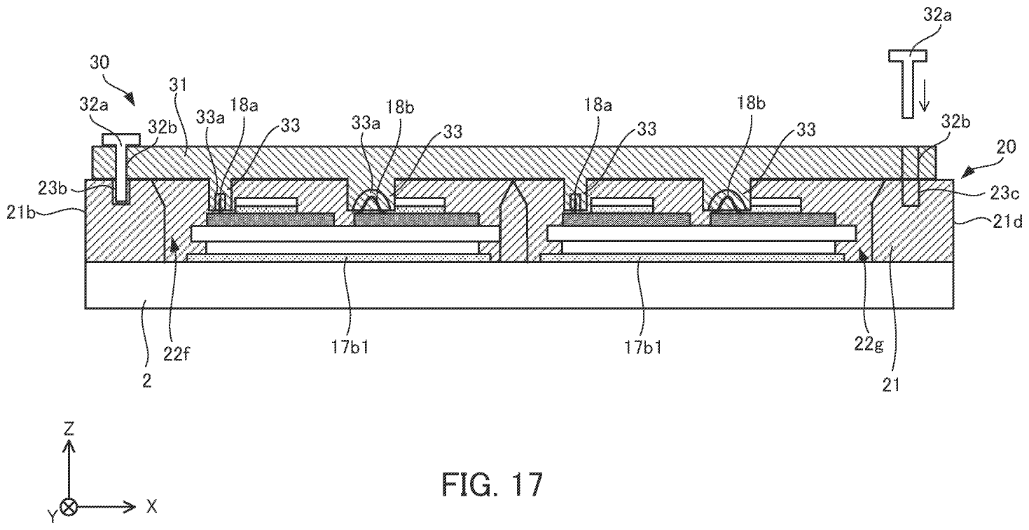

In a modification example 1-1, different fixing parts for fixing a regulating jig 30 to the positioning jig 20 will be described with reference to FIGS. 16 and 17. FIGS. 16 and 17 are sectional views illustrating the bonding step (setting of regulating jig) in the semiconductor device manufacturing method according to the first embodiment (modification example 1-1).

Referring to FIG. 16, fixing projections 25 are formed in the positioning jig 20, in place of the fixing holes 23a to 23d of FIG. 14, and fixing holes 34 are formed in each regulating jig 30, in place of the fixing projections 32 of FIG. 14. As in the case of FIG. 14, this case enables fixing the regulating jigs 30 to the positioning jig 20.

Alternatively, referring to FIG. 17, insertion holes 32b penetrating through the bridging portion 31 are formed in each regulating jig 30, in place of the fixing projections 32 of FIG. 14. In addition, the fixing holes 23a to 23d of the positioning jig 20 are formed to have the same diameters as the insertion holes 32b. Fixing pins 32a are inserted into the fixing holes 23a to 23d from the insertion holes 32b of each regulating jig 30 placed on the positioning jig 20. This enables fixing the regulating jigs 30 to the positioning jig 20.

### Modification Example 1-2

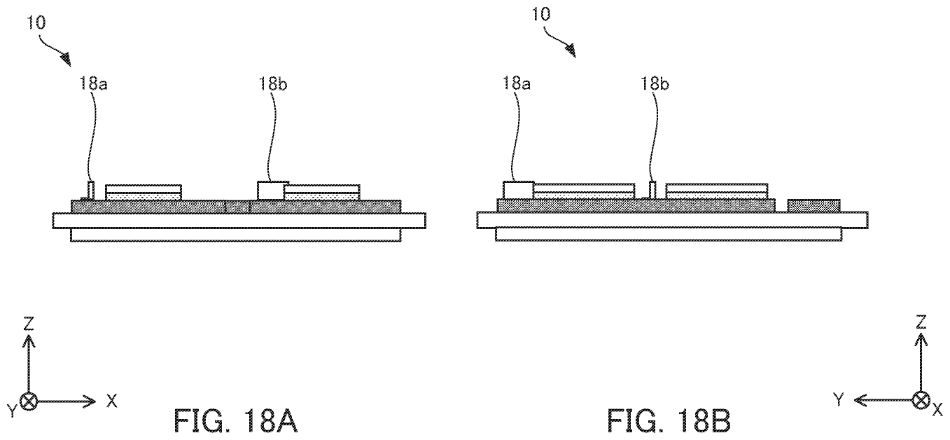

In a modification example 1-2, the case where the regulating members 18a and 18b are made of members other than wires will be described with reference to FIGS. 18A and 18B. FIGS. 18A and 18B illustrate a semiconductor unit provided in the semiconductor device according to the first embodiment (modification example 1-2). In this connection, FIGS. 18A and 18B are sectional views seen from different directions.

The semiconductor unit 10 illustrated in FIGS. 18A and 18B uses connection terminals as the regulating members 18a and 18b, instead of the wires described with reference to FIGS. 2 and 3. The connection terminals have a flat-plate L shape. For example, these regulating members 18a and 18b are bonded to the circuit patterns 13a and 13b by solder or ultrasonic bonding with the regulating markers 13a1 and 13b1 as marks. The heights of the connection terminals bonded to the circuit patterns 13a and 13b from the circuit patterns 13a and 13b may be set in the same manner as the wires. In addition, the widths of the connection terminals may be set in the same manner as the widths of the wires between the bonded portions thereof. In this connection, the depths and widths of the grooves 33b are adjusted according to the heights and widths of the connection terminals. In addition, the grooves 33b are formed such that their groove long-side directions are along the width directions of the connection terminals.

In the case where the regulating members 18a and 18b are the above connection terminals, the regulating members 18a and 18b enter the grooves 33b when the regulating jigs 30 are attached. This makes it possible to prevent the positional shift of the semiconductor unit 10, as in the case of FIGS. 12 and 14. In this connection, the cross sections of the grooves 33b formed in the regulating protrusions 33 in the groove long-side direction may have rectangular shapes corresponding to the shapes of the regulating members 18a and 18b being the connection terminals.

### Second Embodiment

The second embodiment describes, as an example, the case of preventing the positional shift of the semiconductor unit 10 in a different way from the first embodiment. This second embodiment is able to manufacture a semiconductor device in accordance with the flowchart of FIG. 4 as well.

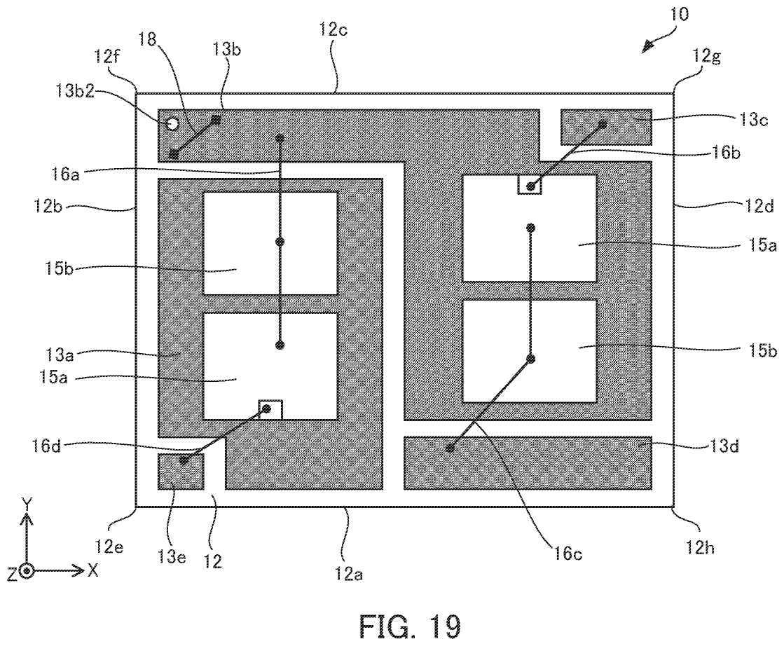

First, as in the first embodiment, a preparation step of preparing semiconductor chips 15a and 15b, an insulated circuit substrate 11, a base substrate 2, and others is executed (step S1). Then, a unit manufacturing step of manufacturing a semiconductor unit 10 and a regulating member forming step of forming a regulating member 18 on the semiconductor unit 10 are executed (steps S2 and S3). The semiconductor unit 10 obtained when the unit manufacturing step is completed is as illustrated in FIGS. 5 and 6. Note that a regulating marker 13b2 is formed only at the corner 12f formed by a long side 12c and short side 12b in a circuit pattern 13b in the semiconductor unit 10 of the second embodiment (see FIG. 19).

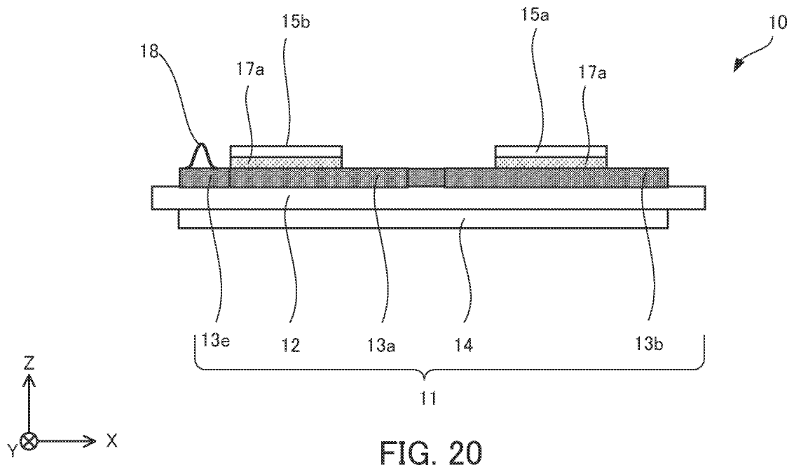

The semiconductor unit 10 obtained when the regulating member forming step is completed will be described with reference to FIGS. 19 and 20. FIG. 19 is a plan view of the semiconductor unit that has a regulating member formed in the regulating member forming step in the semiconductor device manufacturing method according to the second embodiment. FIG. 20 is a side view of the semiconductor unit that has the regulating member formed in the regulating member forming step in the semiconductor device manufacturing method according to the second embodiment. In this connection, FIG. 20 is a side view seen in the +Y direction.

In the semiconductor unit 10 obtained when the regulating member forming step is completed, the regulating member 18 is arranged in the vicinity of the regulating marker 13b2 formed in the circuit pattern 13b of the semiconductor unit 10, with the regulating marker 13b2 as a mark. In the second embodiment, the regulating member 18 is arranged on the outer periphery of the insulated circuit substrate 11. In this connection, the second embodiment describes, just as an example, the case where the regulating member 18 (regulating marker 13b2) is arranged in the vicinity of the corner 12f on the outer periphery of the insulated circuit substrate 11. Alternatively, the regulating member 18 may be arranged anywhere on the outer periphery of the insulated circuit substrate 11. In addition, in the second embodiment, the wiring direction of the regulating member 18 is along the loop shape of the outer periphery of the insulated circuit substrate 11 in plan view. More specifically, the normal line to the wiring direction of the regulating member 18 may be directed toward the center of the insulated circuit substrate 11. In FIG. 19, the normal line is directed toward the corner 12h formed by the long side 12a and short side 12d, which is opposite to the corner 12f formed by the long side 12c and short side 12b. In this connection, the regulating member 18 may be arranged anywhere on the outer periphery of the insulated circuit substrate 11 in such a manner that the normal line to the wiring direction of the regulating member 18 is directed toward the center of the insulated circuit substrate 11.

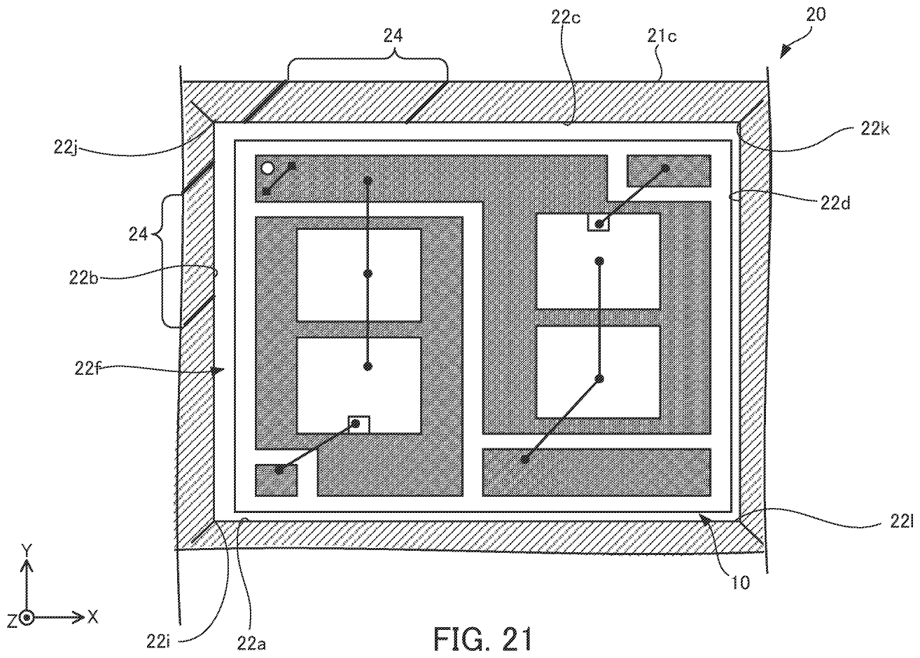

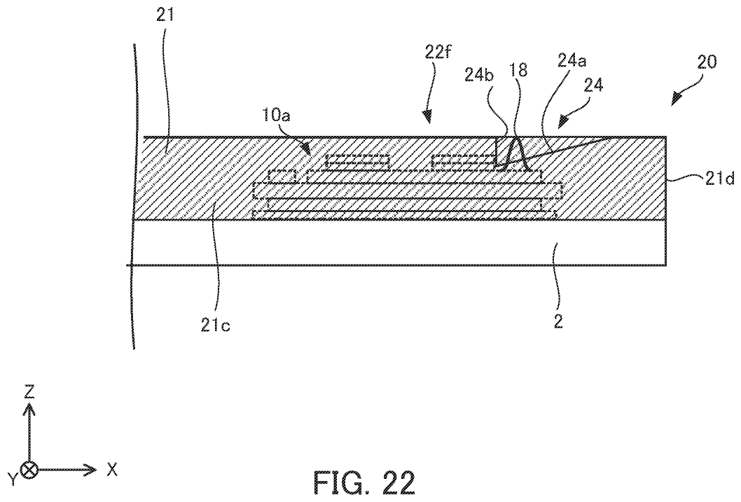

Then, a bonding step of bonding the semiconductor unit 10 obtained at step S3 to the base substrate 2 is executed (step S4 including steps S4a to S4e) First, a positioning jig 20 is placed on the front surface of the base substrate 2, and the semiconductor unit 10 is placed on the base substrate 2 via solder sheets 17b1 using the positioning jig 20 (step S4a and S4b). These steps S4a and S4b will be described with reference to FIGS. 21 and 22. FIG. 21 is a plan view of a main part of the bonding step (setting of positioning jig and arrangement of semiconductor unit) in the semiconductor device manufacturing method according to the second embodiment. FIG. 22 is a side view of a main part of the bonding step (setting of positioning jig and arrangement of semiconductor unit) in the semiconductor device manufacturing method according to the second embodiment. In this connection, FIGS. 21 and 22 illustrate one opening 22f in which the semiconductor unit 10 is arranged. The same description as with the opening 22f is applied to the other openings, and other semiconductor units 10 are arranged in the same manner.

A positioning jig 20 similar to that of the first embodiment is used. The positioning jig 20 of the second embodiment further has notches 24 respectively formed along a pair of two sides of the opening edge of the opening 22. The notches 24 are respectively formed on the opening short side 22b and the opening long side 22c that form the opening corner 22j in the vicinity of the regulating marker 13b1.

Each notch 24 includes an inclined surface 24a and a stoppage surface 24b. The inclined surface 24a of the notch 24 on the opening short side 22b is formed along the opening short side 22b from a position closer to the opening corner 22j formed by the opening short side 22b and opening long side 22c toward the opening corner 22i, whereas the inclined surface 24a of the notch 24 on the opening long side 22c is formed along the opening long side 22c from a position closer to the opening corner 22j toward the opening corner 22k. In addition, each inclined surface 24a is inclined toward the rear surface (−Z direction) of the positioning jig 20 as it goes in the direction from the opening corner 22j formed by the opening short side 22b and opening long side 22c toward the opposite opening corner 22i, 22k of the corresponding one of the opening short side 22b and opening long side 22c. More specifically, each inclined surface 24a is inclined from the opening corner 22j formed by the opening short side 22b and opening long side 22c up to the approximately center point of the corresponding one of the opening short side 22b and opening long side 22c. Each stoppage surface 24b is formed to connect the inclination end of the inclined surface 24a and the front surface of the positioning jig 20 on the corresponding one of the opening short side 22b and opening long side 22c.

Solder sheets 17b1 are placed in disposition areas 2e to 2h of the base substrate 2 through the openings 22e to 22h of the positioning jig 20 placed on the base substrate 2. Then, on the solder sheets 17b1 in the disposition areas 2e to 2h of the base substrate 2, the semiconductor units 10 are placed through the openings 22e to 22h of the positioning jig 20, as illustrated in FIGS. 21 and 22.

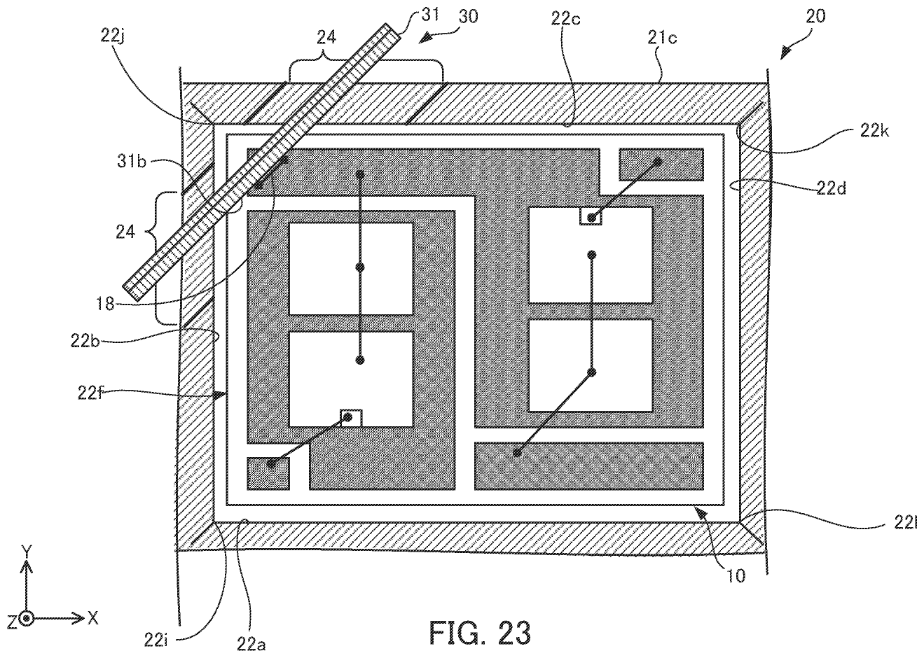

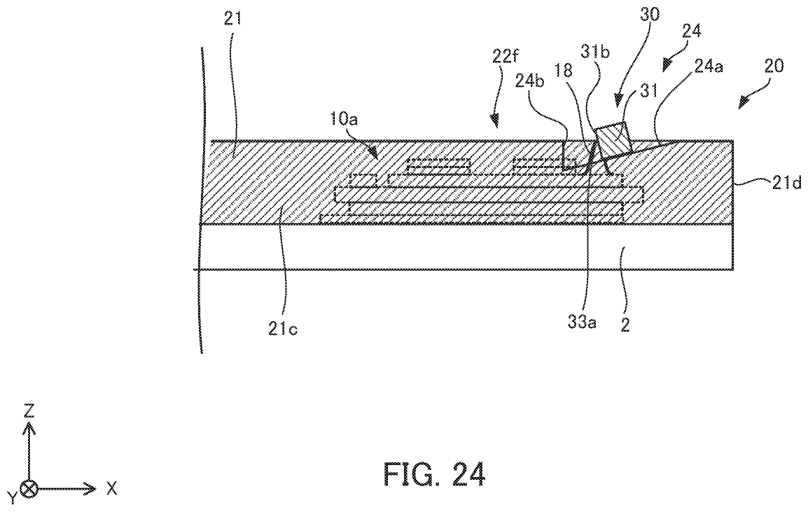

Then, regulating jigs are set on the positioning jig 20 (step S4c). This step S4c will be described with reference to FIGS. 23 and 24. FIG. 23 is a plan view illustrating the bonding step (setting of regulating jig) in the semiconductor device manufacturing method according to the second embodiment. FIG. 24 is a side view illustrating the bonding step (setting of regulating jig) in the semiconductor device manufacturing method according to the second embodiment.

A regulating jig 30 is placed on the positioning jig 20 in which the semiconductor unit 10 is placed, as illustrated in FIGS. 23 and 24. The regulating jig 30 includes a bridging portion 31. The bridging portion 31 has a columnar shape with a regulating surface 31b. When the regulating jig 30 is placed on the positioning jig 20, the regulating surface 31b faces the regulating member 18. That is, the regulating surface 31b is parallel to the wiring direction of the regulating member 18. With such a regulating surface 31b, the cross section of the bridging portion 31 perpendicular to the long-side direction thereof may be rectangular or right triangular. Alternatively, the bridging portion 31 may have a cylindrical shape. In the case of the cylindrical shape, the bridging portion 31 does not include the regulating surface 31b, but contacts the regulating member 18 at a line (at a point in sectional view). In addition, in the case of the cylindrical shape, the regulating jig 30 is likely to roll over the inclined surface 24a of the notch 24.

When one end and the other end of the regulating jig 30 are placed in the notch 24 formed on the opening short side 22b and opening long side 22c, outside the regulating member 18 (on the side closer to the opening corner 22j) on the positioning jig 20, the regulating jig 30 slides the inclined surface 24a of the notch 24. The regulating surface 33a between the one side and the other side of the regulating jig 30 sliding the inclined surface 24a comes into contact with the regulating member 18, as illustrated in FIGS. 23 and 24. Since the regulating jig 30 is placed on the inclined surface 24a, the regulating jig 30 keeps pressing the regulating member 18 downward (along the inclined surface 24a). In this connection, the length of the inclined surface 24a may desirably be set, as long as the regulating jig 30 is able to press the regulating member 18 to bias the semiconductor unit 10 toward the opening corner 22l as will be described later.

In this connection, for example, the width (in the ±Z directions) of the regulating surface 31b is set so that, when the regulating jig 30 contacts the regulating member 18, the width of the regulating surface 31b is greater than the height of the regulating member 18b. The length (in the ±X directions) of the regulating surface 31b is set so that the regulating surface 31b extends over the opening 22 and is placed on the front surface of the positioning jig 20 on the opening short side 22b and opening long side 22c.

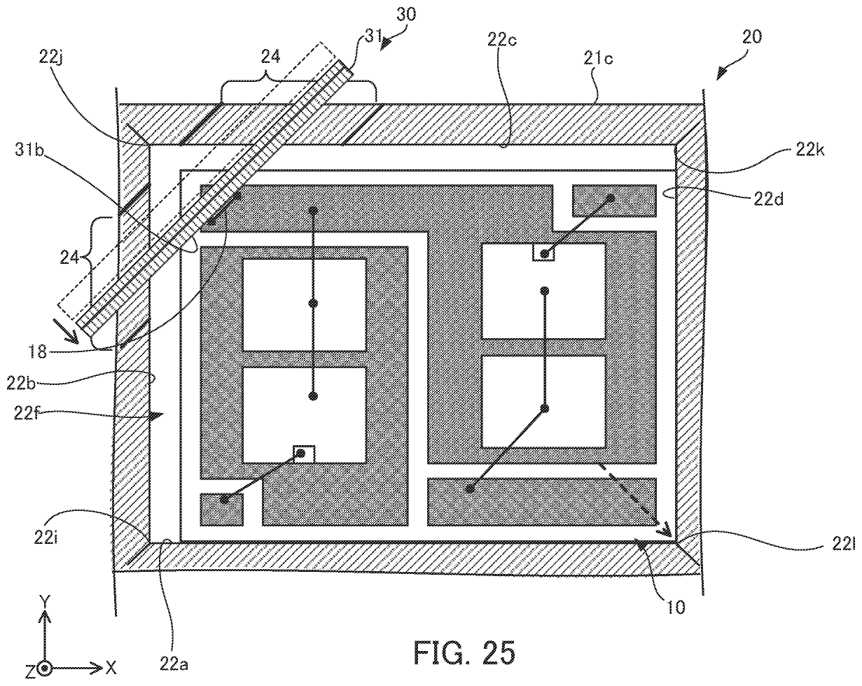

Then, the semiconductor units 10 placed on the base substrate 2 using the positioning jig 20 and the regulating jigs 30 placed on the positioning jig 20 in the manner described above are heated (step S4d). This step S4d will be described with reference to FIG. 25. FIG. 25 is a plan view illustrating the bonding step (heating) in the semiconductor device manufacturing method according to the second embodiment. When heating is carried out at a predetermined temperature, the solder sheet 17b1 is molten, as described earlier. Since the solder sheet 17b1 is molten, the semiconductor unit 10 tends to move on the molten solder sheet 17b1. At this time, as illustrated in FIG. 25, the semiconductor unit 10 is biased toward the opening corner 22l by the regulating member 18 pressing the regulating jig 30 in plan view. Therefore, the semiconductor unit 10 is aligned with the opening corner 221. Thus, the positional shift of the semiconductor unit 10 due to the melting of the solder sheet 17b1 is prevented. The molten solder sheet 17b1 is then solidified to bond the semiconductor unit 10 to the base substrate 2 with the solder 17b. In the manner described above, the semiconductor units 10 are bonded to the disposition areas 2e to 2h on the base substrate 2 with precision, without misalignment.

In this connection, in this case, the openings 22e to 22f are formed in the positioning jig 20 so that the semiconductor units 10 are aligned with the disposition areas 2e to 2h of the base substrate 2, and in addition, the openings 22e to 22f are aligned with the disposition areas 2e to 2h of the base substrate 2. Then, the various jigs used are removed (step S4e). As a result, the semiconductor device 1 is obtained, as in the first embodiment.

### Modification Example 2-1

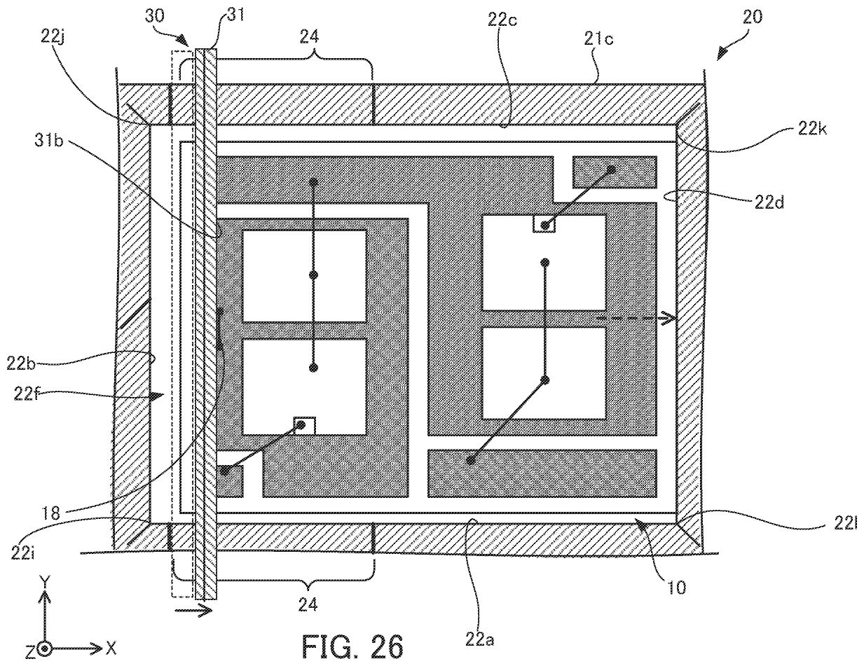

A modification example 2-1 of the second embodiment will be described with reference to FIG. 26. FIG. 26 is a plan view illustrating the bonding step (heating) in the semiconductor device manufacturing method according to the second embodiment (modification example 2-1). The second embodiment describes, as an example, the case where the regulating member 18 is arranged at the corner 12f on the insulated circuit substrate 11 in plan view. Alternatively, the regulating member 18 may be arranged in parallel to any one of the long side 12a, short side 12b, long side 12c, and short side 12d on the insulated circuit substrate 11 in plan view.

For example, in the case where the regulating member 18 is formed at the position of the regulating member 18a of FIG. 2 in the circuit pattern 13a, a notch 24 is formed in the positioning jig 20 on each opening long side 22a and 22c. In addition, the inclined surfaces 24a of the notches 24 are inclined in the −Z direction with respect to the front surface of the positioning jig 20 on the opening long sides 22a and 22c as they go from the opening corners 22i and 22j toward the center points of the opening long sides 22a and 22c, respectively. The regulating jig 30 is placed in the notches 24 formed on the opening long sides 22a and 22c, outside (on the side closer to the opening short side 22b) the regulating member 18 on the positioning jig 20.

When heating is carried out at step S4d, the regulating member 18 of the semiconductor unit 10 is biased by the regulating jig 30 toward the opening short side 22d (in the +X direction) in the semiconductor unit 10, as illustrated in FIG. 26. Therefore, the positional shift of the semiconductor unit 10 in the ±X directions is prevented. In this connection, in this case as well, the length of the inclined surface 24a may desirably be set, as long as the regulating jig 30 is able to press the regulating member 18 and bias the semiconductor unit 10 toward the opening short side 22d.

### Modification Example 2-2

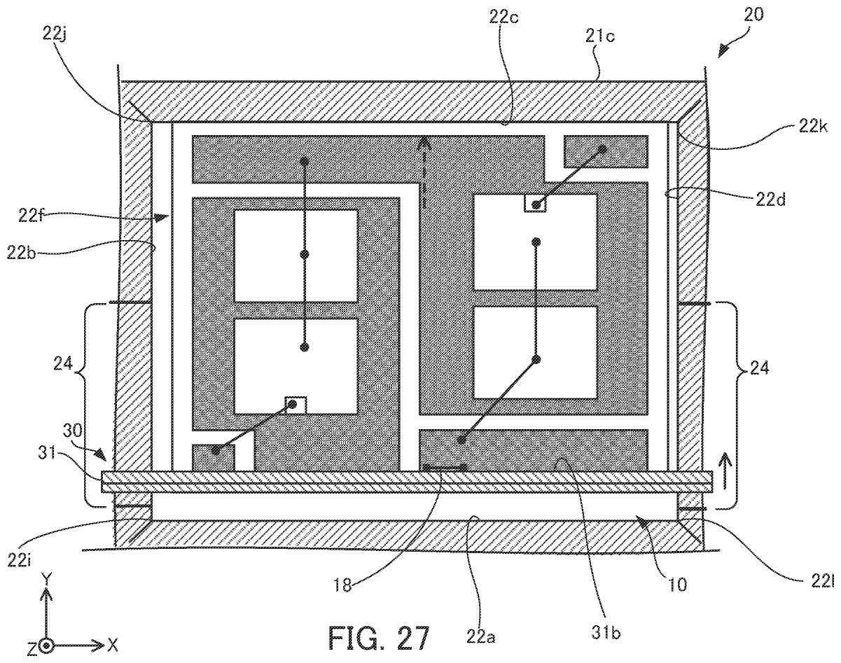

A modification example 2-2 of the second embodiment will be described with reference to FIG. 27. FIG. 27 is a plan view illustrating the bonding step (heating) in the semiconductor device manufacturing method according to the second embodiment (modification example 2-2). The modification example 2-1 describes, as an example, the case where the regulating member 18 is arranged in parallel to the short side 12b on the insulated circuit substrate 11 in plan view. Here, the regulating member 18 is arranged in parallel to the long side 12a on the insulated circuit substrate 11 in plan view.

In the case where the regulating member 18 is formed in parallel to the long side 12a in the circuit pattern 13d (see FIG. 27), for example, notches 24 are formed in the positioning jig 20 on the opening short sides 22b and 22d. In addition, the inclined surfaces 24a of the notches 24 are inclined in the −Z direction with respect to the front surface of the positioning jig 20 on the opening short sides 22b and 22d as they go from the opening corners 22i and 22l toward the center points of the opening short sides 22b and 22d, respectively. The regulating jig 30 is placed in the notches 24 formed on the opening short sides 22b and 22d, outside (on the side closer to the opening long side 22a) the regulating member 18 on the positioning jig 20.

When heating is carried out at step S4d, the regulating member 18 of the semiconductor unit 10 is biased by the regulating jig 30 toward the opening long side 22c (in the +Y direction), as illustrated in FIG. 27. Therefore, the positional shift of the semiconductor unit 10 in the ±Y directions is prevented. In this connection, in this case as well, the length of the inclined surface 24a may desirably be set, as long as the regulating jig 30 is able to press the regulating member 18 and bias the semiconductor unit 10 toward the opening long side 22c.

### Third Embodiment

A third embodiment describes the case where a jig is additionally disposed opposite to the regulating jig 30 in the semiconductor device manufacturing method of the second embodiment, in order to prevent the positional shift of the semiconductor unit 10. A semiconductor device of the third embodiment is manufactured in accordance with the flowchart of FIG. 4 as well.

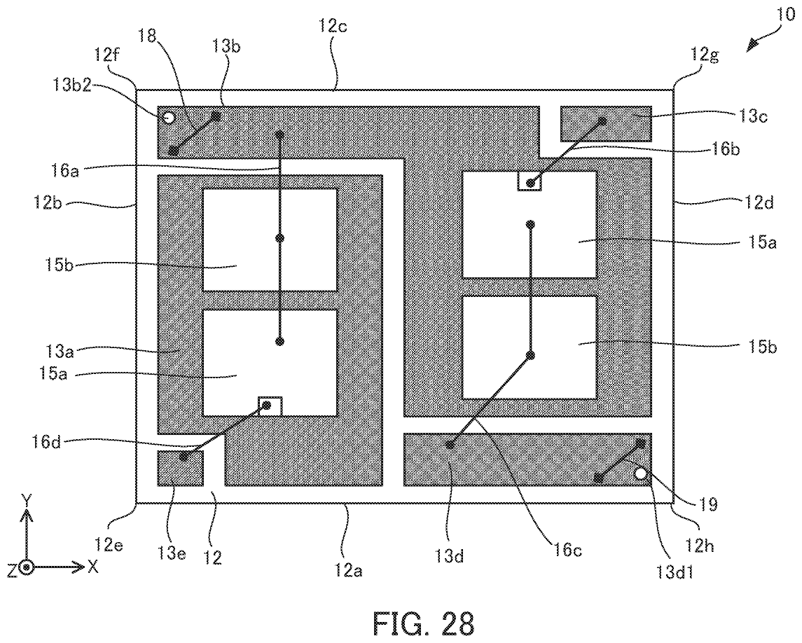

First, as in the first and second embodiments, a preparation step of preparing semiconductor chips 15a and 15b, an insulated circuit substrate 11, a base substrate 2, and others is executed (step S1). Then, a unit manufacturing step of manufacturing a semiconductor unit 10 is executed (step S2). The semiconductor unit 10 obtained when the unit manufacturing step is completed is as illustrated in FIGS. 5 and 6. Note that regulating markers 13b2 and 13d1 are formed at the corner 12f formed by a long side 12c and a short side 12b in a circuit pattern 13b and at the corner 12h formed by a long side 12a and a short side 12d in the circuit pattern 13d, respectively, in the semiconductor unit 10 of the third embodiment (see FIG. 28).

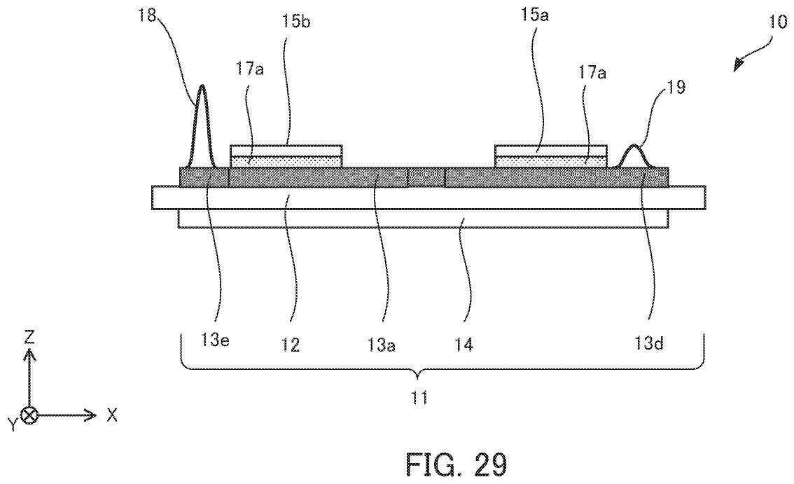

Then, a regulating member forming step of forming a regulating member 18 on the semiconductor unit 10 is executed (step S3). The semiconductor unit 10 having the regulating member 18 formed in the regulating member forming step will be described with reference to FIGS. 28 and 29. FIG. 28 is a plan view of a semiconductor unit having a regulating member and a reference member formed in the regulating member forming step in the semiconductor device manufacturing method according to the third embodiment. FIG. 29 is a side view of the semiconductor unit having the regulating member and reference member formed in the regulating member forming step in the semiconductor device manufacturing method according to the third embodiment. In this connection, FIG. 29 is a side view seen in the +Y direction in FIG. 28.

As in the second embodiment, in the semiconductor unit 10 obtained when the regulating member forming step is completed, the regulating member 18 is arranged in the vicinity of the regulating marker 13b2 formed in the circuit pattern 13b of the semiconductor unit 10, with the regulating marker 13b2 as a mark. In addition, in the third embodiment, a reference member 19 is arranged in the vicinity of the regulating marker 13d1 formed in the circuit pattern 13d, with the regulating marker 13d1 as a mark. The reference member 19 is a wire, as with the regulating member 18. In addition, the reference member 19 may be a connection terminal illustrated in FIGS. 18A and 18B.

In the third embodiment as well, the regulating member 18 and reference member 19 are arranged on the outer periphery of the insulated circuit substrate 11. In addition, the wiring directions of the regulating member 18 and reference member 19 of the third embodiment are along the loop shape of the outer periphery of the insulated circuit substrate 11 in plan view. More specifically, the normal lines to the wiring directions of the regulating member 18 and reference member 19 may be directed toward the center of the insulated circuit substrate 11 in plan view. Referring to FIG. 28, the regulating member 18 and reference member 19 are arranged in the vicinity of the corner 12f formed by the short side 12b and long side 12c and the corner 12h formed by the long side 12a and short side 12d, respectively, such that they are opposite to each other. In this connection, the regulating member 18 and reference member 19 may be arranged anywhere on the outer periphery (in the vicinity of any of all corners) of the insulated circuit substrate 11, as long as they are opposite to each other. In this case, the arrangement in which the regulating member 18 and reference member 19 are opposite to each other means that the wiring directions of the regulating member 18 and reference member 19 are approximately parallel to each other and the normal lines to the wiring directions of the regulating member 18 and reference member 19 approximately match.

In addition, the regulating member 18 preferably has lower rigidity and higher flexibility than the reference member 19. Therefore, the regulating member 18 preferably has a diameter smaller than that of the reference member 19. In addition, as illustrated in FIG. 29, the highest point of the regulating member 18 is preferably higher from the circuit pattern than that of the reference member 19. This makes it easier to bend the regulating member 18.

By contrast, the reference member 19 preferably has higher rigidity and less flexibility than the regulating member 18. Therefore, the reference member 19 preferably has a diameter greater than that of the regulating member 18. In addition, as illustrated in FIG. 29, the highest point of the reference member 19 is preferably lower from the circuit pattern than that of the regulating member 18. This makes it harder to bend the reference member 19.

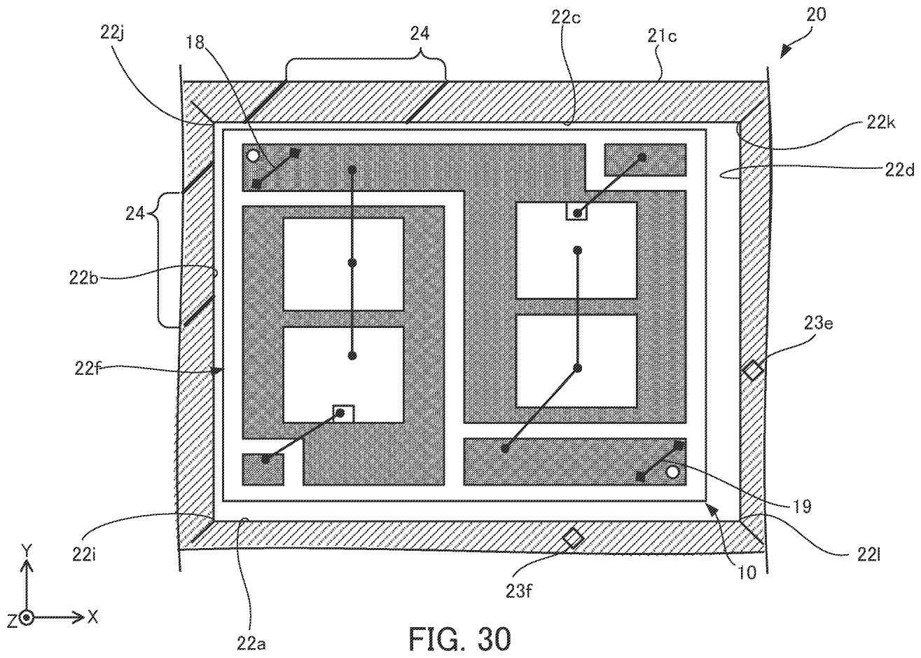

Then, a bonding step of bonding the semiconductor unit 10 obtained at step S3 to the base substrate 2 is executed (step S4 including steps S4a to S4e). First, the positioning jig 20 is placed on the front surface of the base substrate 2, and the semiconductor unit 10 is placed on the base substrate 2 using the positioning jig 20 (step S4a and S4b). These steps S4a and S4b will be described with reference to FIG. 30. FIG. 30 is a plan view of a main part of the bonding step (setting of positioning jig and arrangement of semiconductor unit) in the semiconductor device manufacturing method according to the third embodiment. In this connection, FIG. 30 illustrates one opening 22f in which the semiconductor unit 10 is arranged. The same description as with the opening 22f is applied to the other openings, and other semiconductor units 10 are arranged in the same manner.

A positioning jig 20 similar to that used in the second embodiment is used. The positioning jig 20 of the third embodiment further has fixing holes 23f and 23e on the opening long side 22a and opening short side 22d. The fixing holes 23f and 23e are formed according to the position of the later-described reference jig 40. Solder sheets 17b1 are placed in the disposition areas 2e to 2h of the base substrate 2 through the openings 22e to 22h of the positioning jig 20 placed on the base substrate 2. Then, the semiconductor units 10 are placed on the solder sheets 17b1 in the disposition areas 2e to 2h of the base substrate 2 through the openings 22e to 22h of the positioning jig 20, as illustrated in FIG. 30.

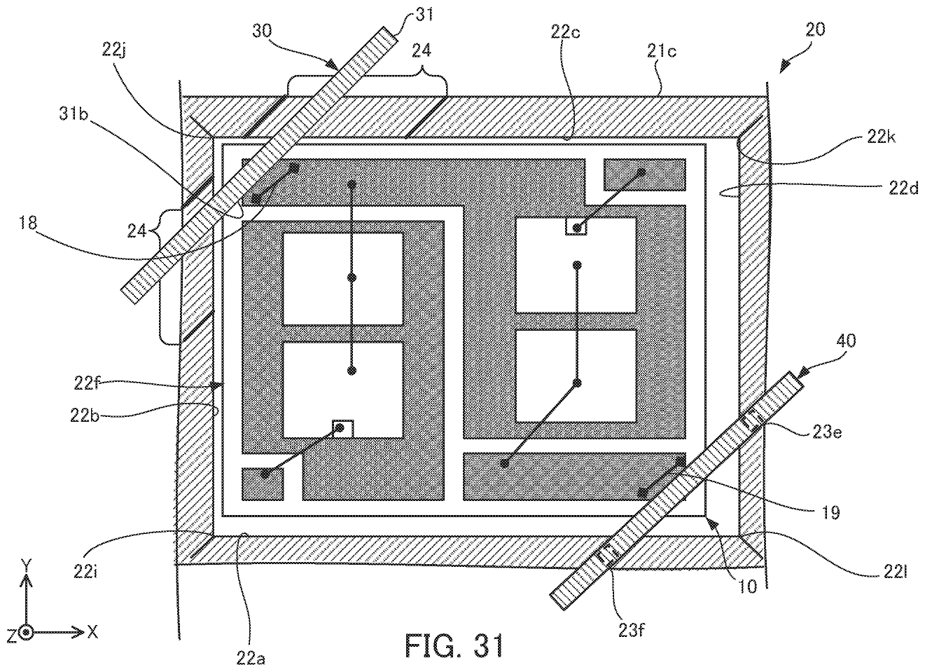

Then, regulating jigs 30 are set on the positioning jig 20 (step S4c). This step S4c will be described with reference to FIG. 31. FIG. 31 is a plan view illustrating the bonding step (setting of regulating jig) in the semiconductor device manufacturing method according to the third embodiment. As illustrated in FIG. 31, a regulating jig 30 is placed on the positioning jig 20 in which the semiconductor unit 10 is placed. This regulating jig 30 has the same shape as that of the second embodiment and is placed on the positioning jig 20 in the same manner. In the third embodiment, the reference jig 40 is additionally placed on the positioning jig 20.

For example, the reference jig 40 has a prismatic shape. Fixing projections (not illustrated) are formed on the surface that faces the positioning jig 20. The fixing projections of the reference jig 40 engage with the fixing holes 23f and 23e. This is the same as the case where the fixing projections 32 of the regulating jig 30 engage with the fixing holes 23b and 23c of the positioning jig 20 as illustrated in FIG. 14. Thereby, the reference jig 40 is fixed to the positioning jig 20. In this connection, the reference jig 40 may be fixed to the positioning jig 20 in the manner described with reference to FIGS. 16 and 17. This reference jig 40 is arranged and fixed outside (on the side closer to the opening corner 221) the reference member 19 on the positioning jig 20.

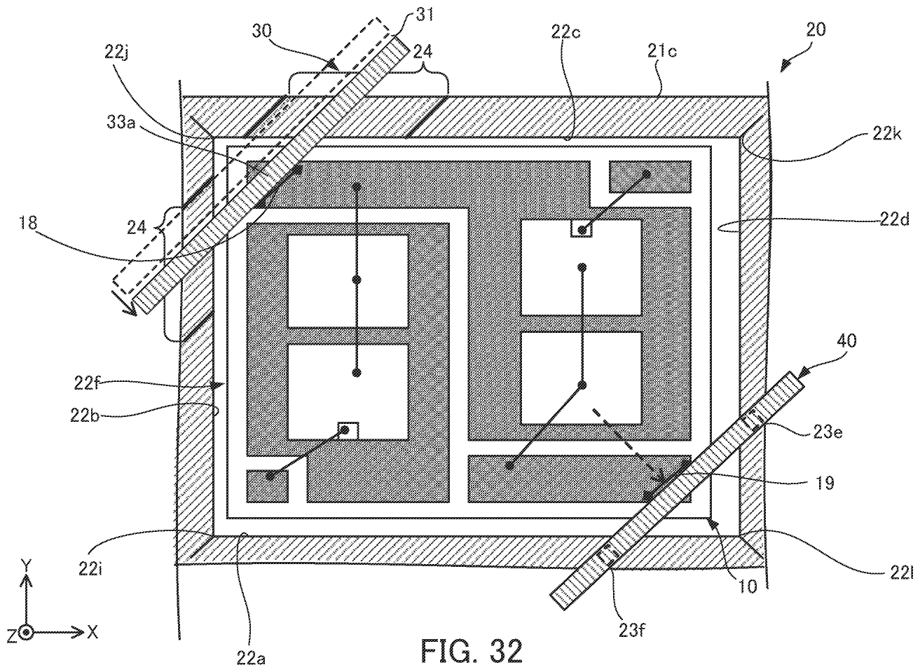

Then, the semiconductor units 10 placed on the base substrate 2 using the positioning jig 20 and the regulating jigs 30 and reference jigs 40 placed on the positioning jig 20 in the manner described above are heated (step S4d). This step S4d will be described with reference to FIG. 32. FIG. 32 is a plan view illustrating the bonding step (heating) in the semiconductor device manufacturing method according to the third embodiment. When heating is carried out at a predetermined temperature, the solder sheet 17b1 is molten, as described earlier. Since the solder sheet 17b1 is molten, the semiconductor unit 10 tends to move on the molten solder sheet 17b1. At this time, as in the second embodiment, the regulating member 18 of the semiconductor unit 10 is biased by the regulating jig 30 toward the opening corner 22l formed by the opening long side 22a and opening short side 22d in plan view. This in turn biases the reference member 19 of the semiconductor unit 10 to come into contact with the reference jig 40. Therefore, the semiconductor unit 10 does not move beyond the reference jig 40 toward the opening corner 221. Especially, since the reference member 19 has higher rigidity than the regulating member 18, the reference member 19 is able to restrict the movement of the biased semiconductor unit 10 without fail. In this connection, in the third embodiment, the length of the inclined surface 24a may desirably be set, as long as the regulating jig 30 is able to press the regulating member 18 and bias the reference member 19 of the semiconductor unit 10 toward the reference jig 40.

Therefore, the positional shift of the semiconductor unit 10 due to the melting of the solder sheet 17b1 is prevented. The molten solder sheet 17b1 is then solidified to bond the semiconductor unit 10 to the base substrate 2 with the solder 17b. In the manner described above, the semiconductor units 10 are bonded to the disposition areas 2e to 2h on the base substrate 2 with precision, without misalignment. Then, the various jigs used are removed (step S4e). As a result, a semiconductor device 1 is obtained, as in the first and second embodiments.

In this connection, in the modification examples 2-1 (FIG. 26) and 2-2 (FIG. 27) of the second embodiment, the reference member 19 may be arranged opposite to the regulating member 18, and the reference jig 40 may be arranged outside the reference member 19 and fixed, as in the third embodiment. By doing so, it is possible to prevent the positional shift of the semiconductor unit 10 in the ±X directions and the ±Y directions, as in the modification example 2-1.

In addition, in the first to third embodiments, the positional shift of the insulated circuit substrate 11 (semiconductor unit) with respect to the base substrate 2 is prevented. For example, even if the circuit patterns 13a to 13e are formed with positional shift on the insulating plate 12 of the insulated circuit substrate 11, the position of the insulated circuit substrate 11 is adjusted, as described in the first to third embodiment. By doing so, it is possible to place the circuit patterns 13a to 13e at positions desired for the semiconductor device 1.

The disclosed techniques make it possible to manufacture a semiconductor device with precision, without misalignment of a substrate with respect to a base substrate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device manufacturing method, comprising:
preparing a semiconductor unit including a semiconductor chip and a substrate to which the semiconductor chip is bonded, and a base substrate having a unit area on a front surface thereof, the unit area being where the substrate of the semiconductor unit is to be disposed;
forming a regulating member on the substrate such that the regulating member protrudes from a front surface of the substrate;
arranging the semiconductor unit in the unit area via a bonding member through an opening area of a positioning jig placed on the front surface of the base substrate, the opening area defining the unit area;
setting a regulating jig having a first end, a second end opposite to the first end, and regulating parts between the first end and the second end, on the positioning jig such that the regulating parts are positioned on sides of the regulating member and the first end and the second end of the regulating jig are respectively positioned on respective opposite sides of an opening edge of the opening area; and
heating the base substrate, the bonding member, and the substrate to bond the substrate to the base substrate.

2. The semiconductor device manufacturing method according to claim 1, wherein
the regulating jig includes a facing surface on a side thereof facing the positioning jig and a groove formed in the facing surface, the groove being entered by the regulating member when the regulating jig is set on the positioning jig in the setting of the regulating jig, the groove having the regulating parts opposite to each other therein, the regulating member entering the groove being positioned between the regulating parts.

3. The semiconductor device manufacturing method according to claim 1, wherein the setting of the regulating jig includes setting the regulating jig on the positioning jig such that the regulating jig is fixed to the opening edge of the opening area by a fixing part.

4. The semiconductor device manufacturing method according to claim 3, wherein the fixing part includes a projection and a fixing hole that engages with the projection, one of the projection and the fixing hole being formed at one of a first position at the opening edge of the opening area of the positioning jig on which the regulating jig is to be placed and a second position on the facing surface of the regulating jig, the first position and the second position overlapping when the regulating jig is placed on the positioning jig, the other one of the projection and the fixing hole being formed at the other one of the first position and the second position.

5. The semiconductor device manufacturing method according to claim 3, wherein the fixing part is a fixing pin that passes through the regulating jig and sticks into the opening edge of the opening area on which the regulating jig is placed.

6. The semiconductor device manufacturing method according to claim 1, wherein the forming of the regulating member includes forming the regulating member on an outer periphery of the substrate.

7. The semiconductor device manufacturing method according to claim 6, wherein
notches each having an inclined surface are respectively formed in the positioning jig along a first pair of two sides of the opening edge of the opening area where the semiconductor unit is arranged, the inclined surface being inclined toward a rear surface of the positioning jig as the inclined surface goes toward a center point of a corresponding one of the first pair of two sides in a plan view of the semiconductor device,
the setting of the regulating jig includes placing the regulating jig in the notches formed in the positioning jig on the first pair of two sides such that the regulating parts face the regulating member, and
during the heating, the regulating jig moves on the inclined surface to bias the regulating member.

8. The semiconductor device manufacturing method according to claim 7, wherein
the forming of the regulating member further includes forming a reference member on the outer periphery of the substrate such that the reference member faces the regulating member,
the setting of the regulating jig further includes setting a reference jig outside the reference member on a front surface of the positioning jig on a second pair of two sides of the opening edge such that the reference jig faces the regulating jig, and
during the heating, the reference member of the semiconductor unit biased by the regulating jig is supported by the reference jig.

9. The semiconductor device manufacturing method according to claim 8, wherein the forming of the regulating member includes forming the regulating member in a vicinity of a first corner of the substrate on the outer periphery of the substrate.

10. The semiconductor device manufacturing method according to claim 9, wherein
the notches are formed in the positioning jig on the first pair of two sides of the opening edge forming the first corner,
the setting of the regulating jig includes setting the regulating jig on the first pair of two sides such that the regulating parts face the regulating member, and
during the heating, the regulating jig moves on the inclined surface to bias the regulating member toward a second corner of the substrate opposite to the first corner.

11. The semiconductor device manufacturing method according to claim 10, wherein the forming of the regulating member includes forming the reference member in a vicinity of the second corner of the substrate.

12. The semiconductor device manufacturing method according to claim 11, wherein the setting of the regulating jig includes setting the reference jig outside the reference member on the front surface of the positioning jig on the second pair of two sides of the opening edge of the opening area forming the second corner.

13. The semiconductor device manufacturing method according to claim 8, wherein
each of the regulating member and the reference member is a wire that has an arched shape to connect two points on the front surface of the substrate, and
as measured from the front surface of the substrate, a highest point of the reference member is lower than a highest point of the regulating member.

14. The semiconductor device manufacturing method according to claim 13, wherein a diameter of the reference member is greater than a diameter of the regulating member.

15. The semiconductor device manufacturing method according to claim 1, wherein the regulating member is a wire that has an arched shape to connect two points on the front surface of the substrate.

16. A semiconductor device, comprising:
a semiconductor chip;
a substrate having a front surface on which the semiconductor chip is disposed and having, on the front surface, a regulating member protruding from the front surface; and
a base substrate on which the substrate is disposed.

17. The semiconductor device according to claim 16, wherein the regulating member is disposed at an outer periphery of the substrate.

18. The semiconductor device according to claim 17, wherein the regulating member is disposed in a vicinity of a first corner of the substrate at the outer periphery of the substrate such that the regulating member faces a second corner of the substrate opposite to the first corner.

19. The semiconductor device according to claim 16, further comprising a reference member at the outer periphery of the front surface of the substrate, the reference member being disposed opposite to the regulating member.

20. The semiconductor device according to claim 19, wherein each of the regulating member and the reference member is a wire that has an arched shape to connect two points on the front surface of the substrate.
